(19) United States
(12) Patent Application Publication
(10) Pub. No.: US 2026/0130185 A1
(43) Pub. Date: May 7, 2026

(54) SEMICONDUCTOR DEVICE WITH IMPROVED BREAKDOWN VOLTAGE AND ASSOCIATED MANUFACTURING METHOD

(71) Applicant: Monolithic Power Systems, Inc., Kirkland, WA (US)

(72) Inventors: Ji-Hyoung Yoo, Los Gatos, CA (US); Yanjie Lian, Chengdu (CN); Daping Fu, Chengdu (CN)

(21) Appl. No.: 18/938,103

(22) Filed: Nov. 5, 2024

(51) Int. Cl. H01L 21/761; H01L 21/8234; H01L 29/66

(52) U.S. Cl. CPC H10W 10/30; H10D 30/0281; H10D 84/0151; H10D 84/0156; H10D 84/038; H10W 10/031

(57) ABSTRACT

A method for forming a semiconductor device having a tub. The method includes forming a substrate of a first conductivity type that includes a tub bottom layer of the tub. The tub bottom layer is of a second conductivity type that is opposite to the first conductivity type and has a tub bottom layer peak dopant concentration plane that is substantially away from a top surface of an initial substrate layer of the substrate for a predetermined tub bottom layer buried depth that is essentially greater than 0.5 μm. The method can further include forming a plurality of tub sidewalls of the tub. The method can further include forming a high voltage transistor inside the tub.

### TECHNICAL FIELD

This disclosure relates generally to semiconductor devices, and more particularly but not exclusively relates to high voltage semiconductor device and associated manufacturing method.

### BACKGROUND

Power transistors, such as high voltage metal-oxide semiconductor (MOS) transistors are widely used in various power management applications, including used as power switching elements in power management devices for industrial and/or consumer electronic equipment. In most high current or high-power applications including notebook, servers, automotive applications etc., transistors with high voltage tolerance capacity are desired.

### BRIEF DESCRIPTION OF DRAWINGS

The following detailed description of various embodiments of the present invention can best be understood when read in conjunction with the following drawings, in which the features are not necessarily drawn to scale but rather are drawn as to best illustrate the pertinent features.

FIG. 1 illustrates a partial cross-sectional view of a semiconductor device 100 in accordance with an embodiment of the present invention.

FIG. 2 illustratively shows a top plan view corresponding to the partial cross-sectional view of the semiconductor device 100 of FIG. 1.

FIG. 3 illustrates a waveform diagram 300 illustrating curves of dopant concentration Cx in cm⁻³ versus a distance Dx in μm away from the top surface S5 of the initial substrate layer 101.

FIG. 4 illustrates a partial cross-sectional view of a semiconductor device 400 in accordance with an alternative embodiment of the present invention.

FIG. 5 illustrates a partial cross-sectional view of a semiconductor device 500 in accordance with an alternative embodiment of the present invention.

FIG. 6 illustrates a partial cross-sectional view of a semiconductor device 600 in accordance with an alternative embodiment of the present invention.

FIG. 7 illustrates a partial cross-sectional view of a semiconductor device 700 in accordance with an alternative embodiment of the present invention.

FIG. 8A to FIG. 8Q illustrate partial cross-sectional views of some process stages of a method for manufacturing a semiconductor device in accordance with an embodiment of the present invention.

### SUMMARY

There has been provided, in accordance with an embodiment of the present disclosure, a semiconductor device having a substrate of a first conductivity type, and a tub of a second conductivity type formed in the substrate, the second conductivity type being opposite to the first conductivity type. The substrate in an embodiment includes an initial substrate layer of the first conductivity type and an epitaxial layer of the first conductivity type formed on the initial substrate layer. The tub in an embodiment includes a tub bottom layer of the second conductivity type buried in the initial substrate layer. The tub bottom layer in an embodiment has a peak dopant concentration plane that is substantially away from a top surface of the initial substrate layer for a predetermined buried depth that is essentially greater than 0.5 μm.

The tub in an embodiment further includes a plurality of tub sidewalls contacting or connected to the tub bottom layer, and each one of the plurality of tub sidewalls extends from a top surface of the substrate down into the substrate until at least reaches to contact or connect with the tub bottom layer.

The semiconductor device in an embodiment further includes a transistor formed in a portion of the substrate located inside the tub. The transistor in an embodiment has a breakdown voltage greater than 70V up to especially over 100V.

There has been provided, in accordance with an embodiment of the present disclosure, a semiconductor device. The semiconductor device has a substrate of a first conductivity type, and a tub of a second conductivity type formed in the substrate, the second conductivity type being opposite to the first conductivity type. The tub in an embodiment includes a tub bottom layer and a plurality of tub sidewalls contacting the tub bottom layer, and each of the plurality of tub sidewalls includes a tub buried link region that is a first buried layer, and the tub bottom layer includes a second buried layer disposed deeper in the substrate than the tub buried link region with reference to a top surface of the substrate. The semiconductor device in an embodiment further includes a transistor formed inside the tub. The transistor in an embodiment has a breakdown voltage greater than 70V up to especially over 100V.

There has also been provided, in accordance with an embodiment of the present disclosure, a method for manufacturing a semiconductor device. The method may include forming a substrate of the first conductivity type that includes a tub bottom layer of a tub. The tub bottom layer is of a second conductivity type that is opposite to the first conductivity type; and has a tub bottom layer peak dopant concentration plane that is substantially away from a top surface of an initial substrate layer of the substrate for a predetermined tub bottom layer buried depth that is essentially greater than 0.5 μm. In an embodiment, the substrate is formed to further include a tub buried link region for each one of a plurality of tub sidewalls of the tub, and the tub buried link region at least contacts with the tub bottom layer. The tub bottom layer is buried deeper than the tub buried link region in the substrate.

In an embodiment, forming the substrate further includes forming an epitaxial layer on the initial substrate layer with the epitaxial layer being formed to have a thickness in a range from 8 μm to 16 μm.

In an embodiment, the method further includes forming a drift region of the second conductivity type for each one of a plurality of transistor cells of a high voltage transistor to be manufactured in the substrate.

In an embodiment, the method may optionally further includes forming a RESURF region of the first conductivity type for each one of the plurality of transistor cells of the high voltage transistor in the epitaxial layer.

In an embodiment, the method may optionally further includes forming a tub wall linking region of the second conductivity type for each one of a plurality of tub sidewalls of the tub in the epitaxial layer. The tub wall linking region can be a buried doped region that is buried substantially at a predetermined tub wall linking depth in the epitaxial layer.

In an embodiment, the method may optionally further includes forming a body well region of the first conductivity type for each one of the plurality of transistor cells of the high voltage transistor to be manufactured in the substrate, wherein the body well region is aside the drift region.

In an embodiment, the method further includes: forming a gate region for each one of the plurality of transistor cells of the high voltage transistor; forming a body region of the first conductivity type for each one of the plurality of transistor cells, wherein the body region is separated from the drift region; forming a source region and a drain region of the second conductivity type for each one of the plurality of transistor cells of the high voltage transistor; forming a tub pickup region for each one of a plurality of tub sidewalls of the tub sharing the same process for forming the source region and the drain region; and forming a body contact region of the first conductivity type for each one of the plurality of transistor cells of the high voltage transistor.

There has also been provided, in accordance with an embodiment of the present disclosure, a method for manufacturing a semiconductor device. The method may include: providing an initial substrate layer of a substrate of a first conductivity type; forming a tub bottom layer of a tub of a second conductivity type in the initial substrate layer, the second conductivity type being opposite to the first conductivity type; and forming a tub buried link region for each one of a plurality of tub sidewalls so that the tub buried link region is formed to at least contact with the tub bottom layer, and the tub bottom layer is buried deeper in the substrate than the tub buried link region with reference to a top surface of the initial substrate layer. The method may further include forming an epitaxial layer on the initial substrate layer, wherein the epitaxial layer is formed to have a thickness substantially ranging from 8 μm to 16 μm. The method may further include forming the plurality of tub sidewalls of the tub and forming a high voltage transistor inside the tub.

### Detailed Description

Various embodiments of the present invention will now be described. In the following description, some specific details, such as example circuits and example values for these circuit components, are included to provide a thorough understanding of embodiments. One skilled in the relevant art will recognize, however, that the present invention can be practiced without one or more specific details, or with other methods, components, materials, etc. In other instances, well-known structures, materials, processes or operations are not shown or described in detail to avoid obscuring aspects of the present invention.

Throughout the specification and claims, the term “coupled,” as used herein, is defined as directly or indirectly connected in an electrical or non-electrical manner. When an element is described as “connected” or “coupled” to another element, it can be directly connected or coupled to the other element, or there could exist one or more intermediate elements. In contrast, when an element is referred to as “directly connected” or “directly coupled” to another element, there is no intermediate element. In addition, “electrically connected” or “electrically coupled” means the concept including a physical connection and a physical disconnection, which enables an electrical coupling between elements. It can be understood that when an element is referred to with “first” or “second” or the like, the element is not limited thereby. The terms “first” or “second” or the like may be used only for a purpose of distinguishing the element from the other elements and may not limit the sequence or importance of the elements unless the context clearly dictates otherwise. The terms “a,” “an,” and “the” include plural reference, and the term “in” includes “in” and “on”. The phrase “in one embodiment,” as used herein does not necessarily refer to the same embodiment, although it may. The term “or” is an inclusive “or” operator, and is equivalent to the term “and/or” herein, unless the context clearly dictates otherwise. The term “based on” is not exclusive and allows for being based on additional factors not described, unless the context clearly dictates otherwise. The term “circuit” means at least either a single component or a multiplicity of components, either active and/or passive, that are coupled together to provide a desired function. The term “signal” means at least one current, voltage, charge, temperature, data, or other signal. Those skilled in the art should understand that the meanings of the terms identified above do not necessarily limit the terms, but merely provide illustrative examples for the terms.

The terms “comprise”, “include”, “have” and any variations thereof, are intended to cover non-exclusive inclusions, such that a process, method, article, or apparatus that comprises a list of elements is not necessarily limited to those elements, but may include other elements not expressly listed or inherent to such process, method, article, or apparatus.

The terms “left,” right,“ ”in,“ ”out,“ ”front,“ ”back,“ ”up,“ ”down, “top,” “atop”, “bottom,” “over,” “under,” “above,” “below”, “lower”, “upper” and the like in the description and the claims, if any, are used for descriptive purposes and for convenience of explanation and not necessarily for describing permanent relative positions. It is to be understood that the terms so used are interchangeable under appropriate circumstances such that embodiments of the invention described herein are, for example, capable of operation in other orientations than those illustrated or otherwise described herein, and the claims are not particularly limited by the positions or directions as described with those terms.

For convenience of explanation, the present disclosure takes an N-channel semiconductor device for example for the explanation, but this is not intended to be limiting and persons of skill in the art will understand that the structure and principles taught herein also apply to P-channel semiconductor devices wherein, for example, the conductivity types of the various regions shown herein are replaced by their opposites, and to other types of semiconductor materials and devices as well. While poly-silicon is preferred for forming the gate used in embodiments of the present disclosure, the embodiments are not limited to this choice of conductor and other types of materials (e.g., metals, other semiconductors, semi-metals, and/or combinations thereof) that are compatible with other aspects of the device manufacturing process may also be used. Thus, the terms “poly” and “poly-silicon” are intended to include such other materials and material combinations in addition to poly-silicon.

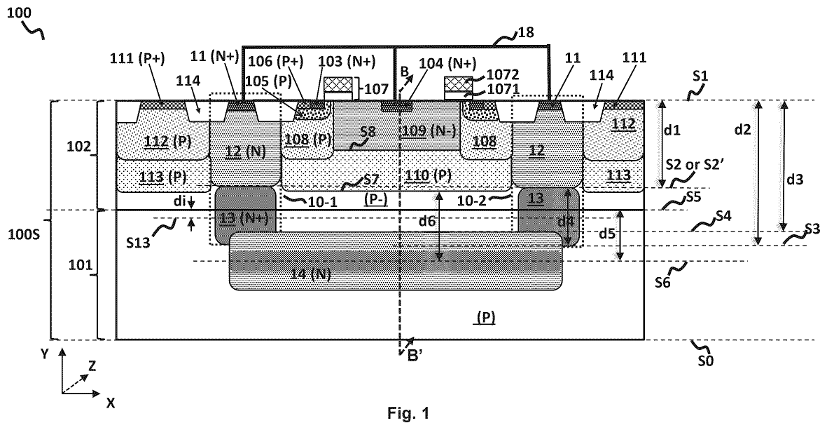

FIG. 1 illustrates a partial cross-sectional view of a semiconductor device 100, including for instance a transistor in accordance with an embodiment of the present disclosure. The cross-sectional view in FIG. 1 may be considered as illustrated out in a 3-dimensional coordinate system having the x axis, y axis and z axis perpendicular to one another. It may be understood that the illustrative cross-sectional view is inspected from/taken from a cutting plane parallel to the x-y plane defined by the x and y axis. Throughout this disclosure, lateral may refer to a direction parallel to the x axis while vertical may refer to a direction parallel to the y axis. Width may refer to a size measured in the direction parallel to the x axis while height may refer to a size measured in the direction parallel to the y axis. The semiconductor device 100 may be formed in/on a substrate 100S including an initial substrate layer 101 of a first conductivity type (e.g., P type). The initial substrate layer 101 may comprise one or more of the semiconductor materials such as Si, Ge, SiC, or other forms of semiconductor layers. The initial substrate layer 101 may have a thickness substantially ranging from 100 μm to 200 μm for example. However, this is just to provide an example and not intended to be limiting. In an example, the initial substrate layer 101 can be doped with dopants of the first conductivity type to have a first dopant concentration (e.g., may also be referred to as a substrate dopant concentration). In an embodiment, the first dopant concentration may be in a range from 1e13 cm⁻³ to 1e16 cm⁻³. As can be understood by those of ordinary skill in the art, the dopant concentration distribution of any single doped region or doped layer in a semiconductor device would be inherently not ideally uniform due to the physics of dopants diffusion, generally a location at where dopants are implanted in to form the doped region or doped layer may have a substantially peak dopant concentration value. Generally, in a practical semiconductor device manufactured, the substantially peak dopant concentration value of a single doped region or a single doped layer may be indicative of a doping degree or alternatively speaking a dopant concentration of that single doped region or that single doped layer. Therefore, it can be understood by those of ordinary skill in the art that throughout the present disclosure, the term “dopant concentration” of a specific single doped region or a specific single doped layer refers to the substantially peak dopant concentration value that can be inspected or measured of the specific single doped region or the specific single doped layer.

A relatively thick epitaxial layer 102 of the first conductivity type (e.g., P type) can be formed on the initial substrate layer 101. Here, in accordance with various embodiments of the present invention, “relatively thick” refers that the epitaxial layer 102 is thick enough to be suitable for supporting the manufacturing of a high voltage transistor having a breakdown voltage no lower than 70V for instance. For example, the epitaxial layer 102 can have a thickness that is thicker than 5 μm. In an embodiment, the epitaxial layer 102 can have a thickness substantially ranging from 8 μm to 16 μm for example to support the forming of a high voltage transistor having a breakdown voltage substantially of about 80V to 250V. In an alternative embodiment, the epitaxial layer 102 can have a thickness substantially ranging from 10 μm to 12 μm for example to support the forming of a high voltage transistor having a breakdown voltage substantially of about 100V to 140V. In still an alternative embodiment, the epitaxial layer 102 can have a thickness substantially ranging from 12 μm to 14 μm for example to support the forming of a high voltage transistor having a breakdown voltage substantially of about 120V to 200V. In yet an alternative embodiment, the epitaxial layer 102 can have a thickness substantially ranging from 14 μm to 16 μm for example to support the forming of a high voltage transistor having a breakdown voltage substantially of about 180V to 250V. A breakdown voltage of a transistor generally indicates a voltage tolerance capacity of the transistor and is one of a plurality of characteristics or parameters of the transistor as well known in the art. For instance, a breakdown voltage of a MOS transistor having a drain, a source and a gate may refer to a maximum drain to source voltage that the MOS transistor may be able to withstand in its OFF state (or non-conduction state).

In an embodiment, the epitaxial layer 102 may comprise one or more of the semiconductor materials such as Si, Ge, SiC, or any other suitable semiconductor materials. In an embodiment, the epitaxial layer 102 may be formed of semiconductor materials identical to those of the initial substrate layer 101. In an embodiment, the epitaxial layer 102 may be doped with dopants of the first conductivity to have a second dopant concentration (e.g., may also be referred to as an epitaxial dopant concentration). The second dopant concentration may be lower than the first dopant concentration. For instance, the epitaxial layer 102 is illustrated by a P-layer in FIG. 1. For instance, in an embodiment, the second dopant concentration may range from 1e13 cm⁻³ to 1e16 cm⁻³. In an embodiment, the second dopant concentration may range from 1e14 cm⁻³ to 1e15 cm⁻³.

The substrate 100S of the semiconductor device 100 in the examples shown collectively includes the initial substrate layer 101 and the epitaxial layer 102. One of ordinary skill in the art would understand that this is not intended to be limiting, in an alternative embodiment, the substrate 100S of the semiconductor device 100 may include more or less semiconductor layers and do not depart from the spirit of the present disclosure. In other alternative embodiments, for example, the substrate 100S of the semiconductor device 100 may include single and/or multiple non-epitaxial or epitaxial semiconductor layers comprising one or more of the semiconductor materials such as Si, Ge, SiC or any other suitable semiconductor materials.

In accordance with an exemplary embodiment of the present invention, the semiconductor device 100 may include a tub formed in the substrate 100S of the semiconductor device 100. The tub may have a tub bottom layer 14 of the second conductivity type (e.g., N type) buried in the initial substrate layer 101. The tub may further have a plurality of tub sidewalls 10 of the second conductivity type (e.g., N type). The second conductivity type (e.g., N type) is opposite to the first conductivity type (e.g., P type). Herein, the term “a plurality of” is not limited to more than one but intended to include one. Each one of the plurality of tub sidewalls 10 may have a substantially predetermined tub wall width (or tub wall thickness) w1. The plurality of tub sidewalls 10 physically contact the tub bottom layer 14 so that they could be electrically connected, and the tub may perform as if it is a container of the second conductivity type embedded in the substrate 100S of the first conductivity type, providing a second conductivity barrier between a portion of the substrate 100S located inside the tub and a portion of the substrate 100S located outside the tub.

In the partial cross-sectional view of FIG. 1 illustratively shown, as an example, a tub left sidewall 10-1 and a tub right sidewall 10-2 among the plurality of tub sidewalls 10 of the tub can be observed. One of ordinary skill in the art would understand that the plurality of tub sidewalls 10 of the tub may form a closed loop and define a top plan view shape of the tub when observed in a top plan view plane defined by the x and z axis.

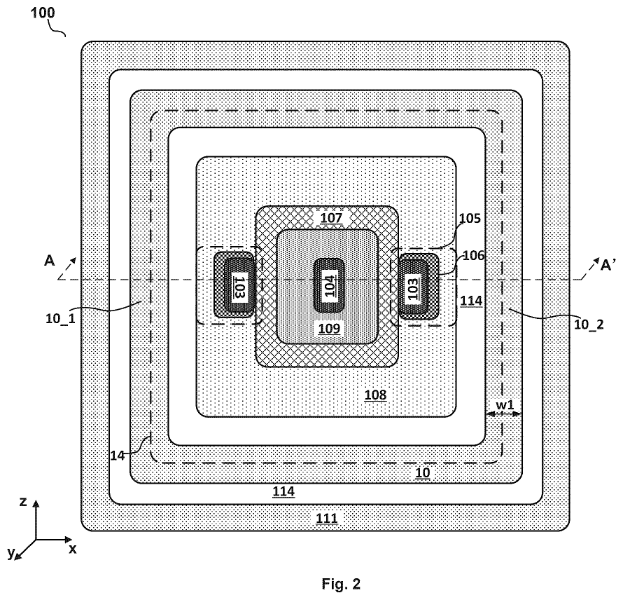

FIG. 2 illustratively shows a top plan view corresponding to the partial cross-sectional view of the semiconductor device 100 of FIG. 1. The partial cross-sectional view illustrated in FIG. 1 may be considered as corresponding to a cross section taken from the cutting line A-A′ in the top plan view of FIG. 2 in accordance with an exemplary embodiment of the present disclosure. In the example of FIG. 2, the top pan view shape of the tub is illustrated as a substantially rectangular ring. It should be understood that the top plan view shape of the tub is not limited, and may be a ring that is substantially rectangular, or quadrilateral, or polygonal, or circular, or of other shapes that are compatible with the manufacturing process.

In accordance with an exemplary embodiment of the present invention, each one of the plurality of tub sidewalls 10 may include a tub pickup region 11, a tub well region 12, and a tub buried link region 13, for instance, referring to the illustration for the tub left sidewall 10-1 or the tub right sidewall 10-2 in the example of FIG. 1 for ease of understanding.

The tub pickup region 11 of each one of the plurality of tub sidewalls 10 (e.g., 10-1 and 10-2) may be formed in the substrate 100S and disposed adjacent a top surface S1 of the substrate 100S opposite to a bottom surface S0 of the substrate 100S. In the example illustratively shown in FIG. 1, the tub pickup region 11 is formed in the epitaxial layer 102 and near a top surface (also labeled with S1) of the epitaxial layer 102. The top surface of the epitaxial layer 102 is also labeled with S1 since the top surface of the epitaxial layer 102 embodies as and may be deemed as the top surface of the substrate 100S which may include the initial substrate layer 101 and the epitaxial layer 102 in the example of FIG. 1. The tub pickup region 11 may be of the second conductivity type (e.g., N type) and may have a tub pickup dopant concentration so that the tub pickup region 11 may serve/function as a contact region of the tub that allows the tub being electrically coupled to for example a metal contact (herein after referred to as a tub metal contact) which may be formed atop the tub pickup region 11. The tub pickup region 11 may help to form an Ohmic contact between each tub sidewall 10 and the tub metal contact, and thus may be referred to as being “highly doped” or “heavily doped” by those skilled in the art (e.g., illustrated as an N+ region in FIG. 1). In an embodiment, the tub pickup dopant concentration may be higher than the first dopant concentration and/or the second dopant concentration. In an embodiment, for example, the tub pickup dopant concentration may be in a range from 1e18 cm⁻³ to 1e21 cm⁻³.

The tub well region 12 of each tub sidewall 10 may be formed and disposed surrounding the tub pickup region 11 and extend vertically from the top surface S1 of the substrate 100S (i.e., the top surface S1 of the epitaxial layer 102 in the example of FIG. 1) into the substrate 100S (e.g., into the epitaxial layer 102 for the example of FIG. 1) with substantially a tub well depth d1. One of ordinary skill in the art would understand that the tub well depth d1 can be considered as a direct vertical distance inspected substantially from the top surface S1 of the substrate 100S (i.e., the top surface S1 of the epitaxial layer 102 in the example of FIG. 1) to a bottom surface S2 of the tub well region 12. The tub well region 12 may be of the second conductivity type (e.g., N type). The tub well region 12 may have a tub well dopant concentration that may be lower than the tub pickup concentration. In the example of FIG. 1, the tub well region 12 is illustratively shown as an N region which may indicate that the tub well dopant concentration is lower than the tub pickup dopant concentration of the tub pickup region 11 illustratively shown as an N+ region, as can be understood by person of ordinary skill in the art. In an embodiment, the tub well dopant concentration may be in a range from 5e16 cm⁻³ to 1e18 cm⁻³.

The tub well region 12 may be doped with dopants of the second conductivity type, such as Phosphorus (P), that are suitable for and compatible with a medium to high energy implantation process, for instance a few hundred keV level to several MeV level implantation process depending on the tub well depth d1 required in practical application and the thickness of the epitaxial layer 102. The tub well region 12 may be formed for instance by using the medium to high energy implantation process to implant in dopants of the second conductivity type (e.g., P) suitable for and compatible with the medium to high energy implantation process from the top surface S1 into the epitaxial layer 102.

In an exemplary embodiment, the tub buried link region 13 of each tub sidewall 10 may be formed and disposed below or underneath the tub well region 12 as illustratively shown in the example of FIG. 1. The tub buried link region 13 may be of the second conductivity type (e.g., N type in the example of FIG. 1). In an embodiment, the tub buried link region 13 may include a first buried layer of the second conductivity type (e.g., N type in the example of FIG. 1) that is buried below the tub well region 12 in each one of the plurality of tub sidewalls 10. In an embodiment, the tub buried link region (i.e., the first buried layer) 13 may be formed in the initial substrate layer 101 and have a first portion (e.g., a lower portion) vertically extended down into the initial substrate layer 101 formed with an implantation process and a follow up drive-in process. The tub buried link region (i.e., the first buried layer) 13 may generally further have a second portion (e.g., an upper portion as illustrated in the example of FIG. 1) vertically extended up into the epitaxial layer 102 due to a phenomenon of auto-doping, i.e., a phenomenon of dopants auto-diffusion without intentionally using a drive-in step, as can be understood by those skilled in the art. In the exemplary embodiment shown in FIG. 1, the tub buried link region 13 may physically contact the tub well region 12 above and the tub bottom layer 14 below to provide an electrical connection between the tub well region 12 and the tub bottom layer 14 so that they are electrically coupled and an electrical path of the second conductivity type (e.g., N type) from the tub pickup region 11 to the tub bottom layer 14 may be formed. In an embodiment, the tub buried link region 13 may have a vertical height d4. In the example shown in FIG. 1, the vertical height d4 may also be considered as a direct vertical distance inspected substantially from a top surface S2′ of the tub buried link region 13 to a bottom surface S3 of the tub buried link region 13. In an example, the top surface S2′ of the tub buried link region 13 may locate in the epitaxial layer 102 while the bottom surface S3 of the tub buried link region 13 may locate in the initial substrate layer 101. In the example of FIG. 1, the top surface S2′ of the tub link region 13 may at least reach and contact with the bottom surface S2 of the tub well region 12 and the tub link region 13 may extend vertically from its top surface S2′ down in the substrate 100S, for instance, into the initial substrate layer 101 with the bottom surface S3 of the first buried link region 13 substantially reaching a tub link depth d2 away from the top surface S1 of the substrate 100S to contact and connect with the tub bottom layer 14. One of ordinary skill in the art would understand that the bottom surface S2 of the tub well region 12 may be substantially coincide and/or coplanar with the top surface S2′ of the tub buried link region 13 in the example of FIG. 1. One of ordinary skill in the art would further understand that in an actual semiconductor device, an interface between adjacent doped regions (such as the interface S2 or S2′ between the tub well region 12 and the tub buried link region 13) may not be as neat, distinct, and clear as theoretically shown in the illustrative drawings of various embodiments of the present disclosure. It is possible that adjacent doped regions may penetrate each other at the interface due to the diffusion of dopants or doped ions during the manufacturing process, making the interface blurred but roughly identifiable.

In accordance with an exemplary embodiment, the tub buried link region 13 may be doped with dopants of the second conductivity type, such as Antimony (Sb) or Arsenic (As), that are suitable for and compatible with a low energy implantation process, for instance a keV level (i.e., 10³ eV level) implantation process. The tub buried link region 13 may be formed for instance by using the low energy (e.g., keV level) implantation process to implant in dopants of the second conductivity type (e.g., Sb or As) that are suitable for and compatible with the low energy (e.g., keV level) implantation process from a top surface S5 of the initial substrate layer 101 into the initial substrate layer 101 before the epitaxial layer 102 is formed atop the initial substrate layer 101. In an embodiment, the low energy (e.g., keV level) implantation process may include implanting dopants with an energy no greater than 200 keV. In an embodiment, the low energy (e.g., keV level) implantation process may include implanting dopants with an energy ranging from 20 keV to 50 keV. The tub buried link region 13 may have a tub link dopant concentration. In an embodiment, the tub link dopant concentration of the tub buried link region 13 may be higher than the tub well dopant concentration of the tub well region 12. In an embodiment, the tub link dopant concentration of the tub buried link region 13 may be at the same order of magnitude as or may be identical to the tub pickup dopant concentration of the tub pickup region 11. In the example of FIG. 1, the tub buried link region 13 is illustratively shown as an N+ region which may indicate that the tub link dopant concentration of the tub buried link region 13 is higher than the tub well dopant concentration of the tub well region 12 illustratively shown as an N region, as can be understood by person of ordinary skill in the art. However, one of ordinary skill in the art would understand that the tub link dopant concentration of the tub buried link region 13 may be different from the tub pickup dopant concentration of the tub pickup region 11. In an embodiment, for example, the tub link dopant concentration may be in a range from 1e17 cm⁻³ to 1e20 cm⁻³.

The tub bottom layer 14 may include a second buried layer of the second conductivity type (e.g., N type in the example of FIG. 1). In an embodiment, the tub bottom layer 14 may be buried in the substrate 100S with a top surface S4 of the tub bottom layer 14 substantially being away from the top surface S1 of the substrate 100S with a buried depth d3. In other words, the buried depth d3 refers to a vertical direct distance inspected substantially from the top surface S1 of the substrate 100S to the top surface S4 of the tub bottom layer 14 being buried in the substrate 100S. In an embodiment, the tub bottom layer (i.e., the second buried layer) 14 may be disposed deeper or lower in the substrate 100S than the tub buried link region (i.e., the first buried layer) 13 relative to (or when inspected or measured with reference to) the top surface S1 of the substrate 100S. In an embodiment, the tub bottom layer (i.e., the second buried layer) 14 may be formed or buried in the initial substrate layer 101. In an embodiment, the tub bottom layer 14 (or alternatively speaking the second buried layer 14) is deeper or lower in the substrate 100S than the tub buried link region 13 (or alternatively speaking the first buried layer 13) in that a bottom surface S14 of the tub bottom layer 14 is deeper or lower than the bottom surface S3 the tub buried link region 13 relative to (or when inspected or measured with reference to) the top surface S1 of the substrate 100S.

In an embodiment, the bottom surface S3 of the tub buried link region 13 may at least reach and contact the top surface S4 of the tub bottom layer 14 and thus may at least be substantially coincide and coplanar with the top surface S4 of the tub bottom layer 14 so that the tub buried link region 13 and the tub bottom layer 14 are linked and connected with each other. In an embodiment, the bottom surface S3 of the tub buried link region 13 may be slightly deeper than the top surface S4 of the tub bottom layer 14 with respect to the top surface S1 of the substrate 100S as exemplarily shown in FIG. 1. As already stated above, one of ordinary skill in the art would understand that in an actual semiconductor device, an interface between adjacent doped regions (such as the interface S2/S2′ between the tub well region 12 and the tub buried link region 13, and the interface between the bottom surface S3 of the tub buried link region 13 and the top surface S4 of the tub bottom layer 14 etc.) may not be as neat, distinct, and clear as theoretically shown in the illustrative drawings of various embodiments of the present disclosure. It is possible that adjacent doped regions may penetrate each other at the interface due to the diffusion of doped ions during the manufacturing process, making the interface blurred but roughly identifiable. This would not be repeated throughout the present disclosure herein after.

In an embodiment, the tub bottom layer 14 may be buried in the initial substrate layer 101 with a peak dopant concentration plane S6 of the tub bottom layer 14 substantially being away from the top surface S5 of the initial substrate layer 101 with a buried depth d5. In other words, the buried depth d5 refers to a vertical direct distance inspected or measured substantially from the top surface S5 of the initial substrate layer 101 to the peak dopant concentration plane S6 of the tub bottom layer 14 being buried in the initial substrate layer 101. One of ordinary skill in the art would understand that the peak dopant concentration plane S6 may refer to the plane positioned at where a substantially peak dopant concentration value of the tub bottom layer 14 is inspected/measured. As can be understood by those of ordinary skill in the art, the dopant concentration distribution of any single doped region in a semiconductor device would be inherently not ideally uniform due to the physics of dopants diffusion, generally a location at where dopants are implanted in to form the doped region may have a substantially peak dopant concentration value. The location at where the dopants are implanted in would be herein after referred to as an implanting-in location for ease of description. Dopant concentration of the doped region generally gradually decrease from the implanting-in location toward locations further away from the implanting-in location as can be understood by those of ordinary skill in the art. The peak dopant concentration plane S6 may thus be alternatively referred to as an implanting-in plane for forming the tub bottom layer 14, the buried depth d5 may alternatively be referred to as an implantation depth for forming the tub bottom layer 14. In accordance with various embodiments of the present invention, the buried depth d5 may be essentially greater than 0.5 μm. In an exemplary embodiment, the buried depth d5 may be essentially in a range from 1 μm to 5 μm. In an alternative exemplary embodiment, the buried depth d5 may be essentially in a range from 1 μm to 3.5 μm.

In an embodiment, the tub bottom layer 14 (or alternatively speaking the second buried layer 14) is deeper or lower in the substrate 100S than the tub buried link region 13 (or alternatively speaking the first buried layer 13) in that the peak dopant concentration plane S6 of the tub bottom layer 14 is deeper or lower than a peak dopant concentration plane S13 of the tub buried link region 13 relative to (or when inspected or measured with reference to) the top surface S5 of the initial substrate layer 101. One of ordinary skill in the art would understand that the peak dopant concentration plane S13 may refer to the plane positioned at where a substantially peak dopant concentration value of the tub buried link region 13 is inspected/measured. The peak dopant concentration plane S13 of the tub link region 13 may alternatively be referred to as an implanting-in plane for forming the tub link region 13. In an embodiment, the peak dopant concentration plane S6 of the tub bottom layer 14 is essentially of 0.5 μm to 3.5 μm deeper than the peak dopant concentration plane S13 of the tub buried link region 13, when inspected or measured with reference to the top surface S5 of the initial substrate layer 101. In an embodiment, the peak dopant concentration plane S6 of the tub bottom layer 14 is essentially of 1 μm to 2 μm deeper than the peak dopant concentration plane S13 of the tub buried link region 13 relative to (or when inspected or measured with reference to) the top surface S5 of the initial substrate layer 101.

In an embodiment, the tub bottom layer 14 may be doped with dopants of the second conductivity type, such as Phosphorus (P), that are suitable for and compatible with a high energy implantation process, for instance a MeV level (i.e., 10⁶ eV level) implantation process. In an embodiment, the high energy (e.g., MeV level) implantation process may include implanting dopants with an energy no lower than 1 MeV. In an embodiment, the high energy (e.g., MeV level) implantation process may include implanting dopants with an energy of about 1 MeV to 4 MeV. The tub bottom layer 14 may be formed for instance by using the high energy (e.g., MeV level) implantation process to implant in dopants of the second conductivity type (e.g., P) suitable for and compatible with the high energy (e.g., MeV level) implantation process from the top surface S5 of the initial substrate layer 101 into the initial substrate layer 101 before the epitaxial layer 102 is formed atop the initial substrate layer 101. In an embodiment, the tub bottom layer 14 may have a tub bottom layer dopant concentration that is lower than (for example, of about 1e1 cm⁻³ to 1e3 cm⁻³ lower than) a dopant concentration of a buried region/buried layer that would be formed in the initial substrate layer 101 with the relatively low energy (e.g., keV level) implantation process. For instance, in an embodiment, the tub bottom layer 14 may have a tub bottom layer dopant concentration that may be lower than the tub link dopant concentration of the tub buried link region 13. For further instance, the tub bottom layer dopant concentration may be of about 1e1 cm⁻³ to 1e3 cm⁻³ lower than the tub link dopant concentration of the tub buried link region 13 which is formed by using the relatively low energy (e.g., keV level) implantation process. Or alternatively speaking, the tub bottom layer dopant concentration of the tub bottom layer 14 may be 1 order of magnitude to 3 orders of magnitude lower than a dopant concentration of a buried region/buried layer (such as the tub link dopant concentration of the tub buried link region 13) that would be formed in the initial substrate layer 101 with the relatively low energy (e.g., keV level) implantation process. In an embodiment, for example, the tub bottom layer dopant concentration may be in a range from 5e15 cm⁻³ to 1e18 cm⁻³, which is not limited and could be alternatively higher but no higher than 1e19 cm⁻³. In the example of FIG. 1, the tub bottom layer 14 is illustratively shown as an N region which may indicate that the tub bottom layer dopant concentration is lower than the tub link dopant concentration of the tub buried link region 13 illustratively shown as an N+ region, as can be understood by persons of ordinary skill in the art. An area near the implanting-in plane S6 illustratively shown with a darker bar in FIG. 1 indicates that the tub bottom layer dopant concentration is higher at that area, and that the tub bottom layer dopant concentration decreases from the area near the implanting-in plane S6 towards areas further away from the implanting-in plane S6 within the tub bottom layer 14.

Conventionally, in addition to the first buried layer 13, it would not be possible to form a second buried layer (such as the second buried layer 14) that can be disposed deeper or lower in the substrate 100S than the first buried layer 13. Unlike conventionally using the relatively low energy (e.g., keV level) implantation process to drive in dopants of the second conductivity type (e.g., Sb or As) suitable for and compatible with the low energy (e.g., keV level) implantation process into the initial substrate layer 101 which cannot form a buried layer with a peak dopant concentration plane of the buried layer being substantially buried beneath the top surface S5 of the initial substrate layer 101 for a buried depth (labelled or noted with di herein after) essentially greater than 0.5 μm, the tub bottom layer 14 doped with dopants of the second conductivity type (e.g., P) suitable for and compatible with the high energy (e.g., MeV level) implantation process according to various embodiments of the present disclosure may advantageously have the buried depth d5 substantially deeper than 0.5 μm. For instance, the buried depth d5 may be substantially deeper than 1 μm in an embodiment. This would be helpful to permit the semiconductor device 100 to have a larger tub well depth d1 of the tub well region 12, and/or a larger tub link depth d2 of the bottom surface S3 of the first buried link region 13, and/or a larger buried depth d3 of the top surface S4 of the tub bottom layer 14, and/or a larger vertical height d4 of the buried link region 13 than it would be conventionally possible, which is beneficial to forming a high voltage transistor in the tub so that the high voltage transistor may have an improved breakdown voltage.

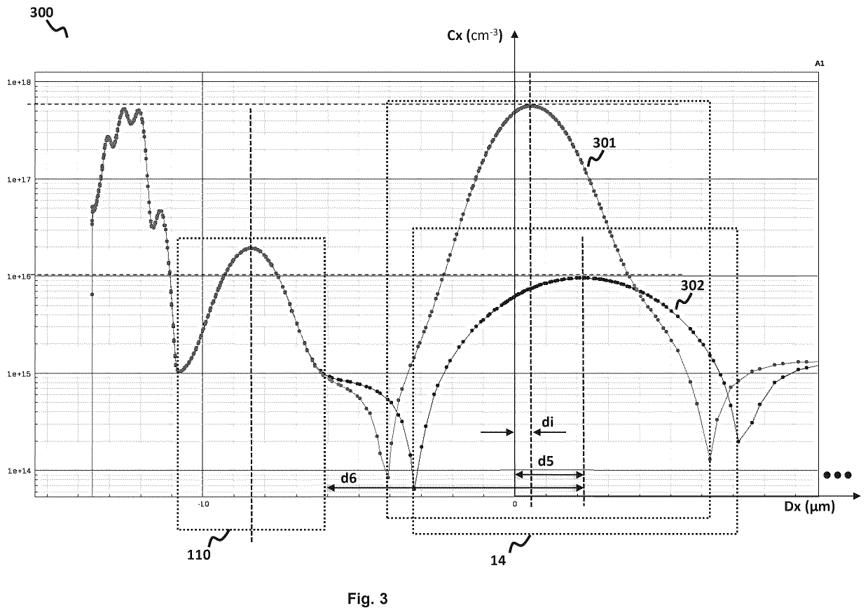

FIG. 3 illustrates a waveform diagram 300 illustrating a first curve 301 showing dopant concentration Cx in cm⁻³ versus a distance Dx in μm away from the top surface S5 of the initial substrate layer 101 for the semiconductor device 100 along the cutting line BB′ in accordance with an embodiment of the present invention and a second curve 302 showing dopant concentration Cx in cm⁻³ versus the distance Dx in μm from the top surface S5 of the initial substrate layer 101 as it would be if the semiconductor device 100 used the relatively low energy (e.g., keV level) implantation process to form the buried layer intended to be used as the tub bottom layer 14. In the waveform diagram 300, the horizontal axis is indicative of the distance Dx in μm and the vertical axis perpendicular to the horizontal axis is indicative of the dopant concentration Cx in cm⁻³. The zero point (Dx=0 μm) is indicative of a reference position where the top surface S5 of the initial substrate layer 101 is located, the distance Dx away from the top surface S5 of the initial substrate layer 101 towards the top surface S1 of the epitaxial layer 102 is plotted in negative distance value while the distance Dx away from the top surface S5 of the initial substrate layer 101 towards the bottom surface S0 of the substrate 100S is plotted in positive distance value. It should be understood by those of ordinary skill in the art that, only a portion (for example the portion including the tub bottom layer 14) of the initial substrate layer 101 (which is indicated by the distance Dx plotted in positive distance value) is shown in the diagram 300 and a remained portion of the initial substrate layer 101 not shown is indicated by the dotted ellipsis in FIG. 3. As can be seen from FIG. 3 that the buried depth d5 of the tub bottom layer 14 of the semiconductor device 100 in accordance with an embodiment of the present invention is substantially 2.1 μm, referring to the first curve 301. In comparison, referring to the second curve 302, if the semiconductor device 100 used the relatively low energy (e.g., keV level) implantation process to form the buried layer intended to be used as the tub bottom layer 14, that buried layer would just have the buried depth di (i.e., a vertical direct distance inspected substantially from the top surface S5 of the initial substrate layer 101 to the peak dopant concentration plane of that buried layer) of substantially 0.5 μm.

The semiconductor device 100 in accordance with various embodiments of the present invention may have the tub bottom layer 14 with the buried depth d5 greater than (for example substantially of 0.5 μm˜3.5 μm greater than) it would be possible if the tub bottom layer 14 were doped with dopants of the second conductivity type (e.g., Sb or As) suitable for and compatible with the low energy (e.g., keV level) implantation process into the initial substrate layer 101. To provide an example, the buried depth d5 is substantially of 1 μm˜2 μm greater than it would be possible if the tub bottom layer 14 were doped with dopants of the second conductivity type (e.g., Sb or As) suitable for and compatible with the low energy (e.g., keV level) implantation process into the initial substrate layer 101. To provide another example, the buried depth d5 of the tub bottom layer 14 would be of essentially 0.5 μm˜3.5 μm greater than the buried depth di of a buried region/buried layer (such as the tub buried link region 13) that would be formed in the initial substrate layer 101 with the relatively low energy (e.g., keV level) implantation process. To provide yet another example, the buried depth d5 of the tub bottom layer 14 would be of essentially 1 μm˜2 μm greater than the buried depth di of a buried region/buried layer (such as the tub buried link region 13) that would be formed in the initial substrate layer 101 with the relatively low energy (e.g., keV level) implantation process.

It can also be seen from FIG. 3 that the tub bottom layer dopant concentration of the tub bottom layer 14 of the semiconductor device 100 in accordance with an embodiment of the present invention has a substantially peak dopant concentration value of essentially 1e16 cm⁻³ at the peak dopant concentration plane S6 of the tub bottom layer 14, referring to the first curve 301. As already been addressed, one of ordinary skill in the art would use the substantially peak dopant concentration value of the tub bottom layer 14 that can be measured in the semiconductor device 100 when practically manufactured to indicate or represent the dopant concentration of the tub bottom layer 14. In comparison, referring to the second curve 302, if the semiconductor device 100 used the relatively low energy (e.g., keV level) implantation process to form the buried layer intended to be used as the tub bottom layer 14, that buried layer would have a buried layer dopant concentration with a substantially peak dopant concentration value of essentially 6e17 cm⁻³ at the peak dopant concentration plane of that buried layer.

The semiconductor device 100 in accordance with various embodiments of the present invention may have the tub bottom layer 14 having the tub bottom layer dopant concentration with a peak dopant concentration value lower than (e.g., substantially of 1e1 cm⁻³ to1e3 cm⁻³ lower than) it would be if the tub bottom layer 14 were doped with dopants of the second conductivity type (e.g., Sb or As) suitable for and compatible with the low energy (e.g., keV level) implantation process into the initial substrate layer 101, which is beneficial to improving the breakdown voltage of the semiconductor device 100. That is, the tub bottom layer dopant concentration of the tub bottom layer 14 can be substantially of 1e1 cm⁻³ to 1e3 cm⁻³ lower than a dopant concentration of a buried region or buried layer (such as the buried link region 13) that would be formed in the initial substrate layer with the low energy implantation process.

In accordance with an exemplary embodiment of the present invention, the semiconductor device 100 may include the high voltage transistor formed in the portion of the substrate 100S located inside the tub. In an embodiment, for example, the high voltage transistor may include a plurality of transistor cells. Herein, the term “a plurality of” is not limited to more than one but intended to include one. In the example illustratively shown in FIG. 1, two transistor cells are exemplarily illustrated out just for helping to understand the embodiments and not intended to be limiting.

For each one of the plurality of transistor cells, a source region (e.g., which may function as a MOSFET source region in an example) 103 may be formed in the substrate 100S and disposed adjacent the top surface S1 of the substrate 100S. In the example illustratively shown in FIG. 1, the source region 103 may be formed in the epitaxial layer 102 and near the top surface (also labeled with S1) of the epitaxial layer 102 for each one of the plurality of transistor cells. The source region 103 may be of the second conductivity type (e.g., N type) and may have a source dopant concentration so that the source region 103 may serve/function as a source region of the high voltage transistor formed in the tub, and thus may be referred to as being “highly doped” or “heavily doped” by those skilled in the art (e.g., illustrated as an N+ region in FIG. 1). In an embodiment, the source dopant concentration may be higher than the tub well dopant concentration of the tub well region 12. In an embodiment, for example, the source dopant concentration may be in a range from 1e19 cm⁻³ to 5e20 cm⁻³.

In accordance with an exemplary embodiment of the present invention, for each one of the plurality of transistor cells, a drain region (e.g., which may function as a MOSFET drain region in an example) 104 may be formed in the substrate 100S and disposed adjacent the top surface S1 of the substrate 100S. In the example illustratively shown in FIG. 1, the drain region 104 may be formed in the epitaxial layer 102 and near the top surface (also labeled with S1) of the epitaxial layer 102 for each one of the plurality of transistor cells. The drain region 104 is separated from the source region 103 in each one of the plurality of transistor cells. The drain region 104 may be of the second conductivity type (e.g., N type) and may have a drain dopant concentration so that the drain region 104 may serve/function as a drain region of the high voltage transistor formed in the tub, and thus may be referred to as being “highly doped” or “heavily doped” by those skilled in the art (e.g., illustrated as an N+ region in FIG. 1). In an embodiment, the drain dopant concentration may be higher than the tub well dopant concentration of the tub well region 12. In an embodiment, for example, the drain dopant concentration may be in a range from 1e19 cm⁻³ to 5e20 cm⁻³.

In accordance with an exemplary embodiment, the tub is electrically coupled with the drain region 104 of the high voltage transistor formed in the tub, as illustratively shown in FIG. 1 for example, the drain region 104 is coupled with the tub pickup region 11 by a connecting wiring structure 18.

In accordance with an exemplary embodiment, a body region 105 of the first conductivity type (e.g., P type) may be disposed surrounding the source region 103 of each one of the plurality of transistor cells in the substrate 100S (e.g., in the epitaxial layer 102 for the example of FIG. 1). In the example of FIG. 1, the body region 105 is illustratively shown as a P region. The body region 105 may have a body dopant concentration. In an embodiment, the body dopant concentration may be in a range from 5e16 cm⁻³ to 1e18 cm⁻³.

In accordance with an exemplary embodiment, for each one of the plurality of transistor cells, a body contact region 106 of the first conductivity type (e.g., P type) may be formed closely next to or in adjoining neighbor to the source region 103 in the substrate 100S. The body contact region 106 may be disposed adjacent to the top surface S1 of the substrate 100S and laterally next to or neighboring to the source region 103. In the example illustratively shown in FIG. 1, the body contact region 106 may be formed closely next to or in adjoining neighbor to the source region 103 in each one of the plurality of transistor cells in the epitaxial layer 102. In the example of FIG. 1, the body contact region 106 is illustratively shown as a P+ region. The body contact region 106 may have a body contact dopant concentration. The body contact dopant concentration may be higher than the body dopant concentration. In an embodiment, for example, the body contact dopant concentration may be in a range from 5e18 cm⁻³ to 1e20 cm⁻³. In accordance with an exemplary embodiment of the present invention, the body contact region 106 may contact the source region 103 and the body region 105 to electrically connect to the source region 103 and the body region 105.

In accordance with an exemplary embodiment of the present invention, for each one of the plurality of transistor cells, a gate region 107 may be formed near the source region 103 side between the source region 103 and the drain region 104. For each one of the plurality of transistor cells, the gate region 107 may in an example be disposed on the top surface S1 of the substrate 100S (e.g., on the top surface S1 of the epitaxial layer 102 in the example of FIG. 1) and at least overlying a portion of the body region 105 so that a channel region may be formed. The gate region 107 may include a gate dielectric layer 1071 and a gate conductive layer 1072. One of ordinary skill in the art would understand that the gate region 107 as illustrated in the example of FIG. 1 is just a simplified example for illustrative purpose. The gate region 107 may take various structures that do not depart from the spirit and scope of the present invention. For instance, in an embodiment, the gate dielectric layer 1071 may include a thin gate dielectric portion and a thick gate dielectric portion relatively thicker than the thin gate dielectric portion. The thin gate dielectric portion may be positioned atop a portion of the epitaxial layer 102 near the source region 103 side and the thick gate dielectric portion may be positioned atop a portion of the epitaxial layer 102 between the thin gate dielectric portion and the drain region 104. The gate conductive layer 1072 may be disposed to at least overlay a portion of the thin gate dielectric portion and a portion of the thick gate dielectric portion. For another instance, the thick gate dielectric portion may be replaced by a shallow trenched dielectric structure disposed in a shallow trench formed in a portion of the epitaxial layer 102 substantially between the thin gate dielectric portion and the drain region 104. A conductive field plate having at least a portion disposed in the shallow trenched dielectric structure can further be formed.

In accordance with an exemplary embodiment of the present invention, for each one of the plurality of transistor cells, a drift region 109 may further be formed in the substrate 100S surrounding the drain region 104. For each one of the plurality of transistor cells, the drift region 109 may extend towards the source region 103 and separated from the source region 103. In an embodiment, the drift region 109 of each one of the plurality of transistor cells may laterally extend from the drain region 104 towards the source region 103 such that a portion of the drift region 109 may be underlying a portion of the gate region 107. Or alternatively speaking, the gate region 107 may include a portion overlying a portion of the drift region 109. In an embodiment, the drift region 109 of each one of the plurality of transistor cells may be of the second conductivity type (e.g., N type) and may have a drift dopant concentration. In an embodiment, the drift dopant concentration may be lower than the drain dopant concentration. In the example of FIG. 1, the drift region 109 is illustratively shown as an N-well region which may indicate that the drift dopant concentration is lower than the drain dopant concentration of the drain region 104 illustratively shown as an N+ doped region, as can be understood by persons of ordinary skill in the art. In an example, the drift dopant concentration of the drift region 109 may be in a range from 5e15cm⁻³ to 5e17 cm⁻³.

In accordance with an exemplary embodiment of the present invention, for each one of the plurality of transistor cells, a body well region 108 may optionally be formed surrounding the body region 105 of each one of the plurality of transistor cells in the substrate 100S (e.g., in the epitaxial layer 102 for the example of FIG. 1). In an embodiment, the body well region 108 of each one of the plurality of transistor cells may be of the first conductivity type (e.g., P type). In the example of FIG. 1, the body well region 108 is illustratively shown as a P region. The body well region 108 may have a body well dopant concentration. In an embodiment, the body well dopant concentration of the body well region 108 may be lower than the body dopant concentration of the body region 105. In an embodiment, the body well dopant concentration of the of the body well region 108 may be in a range from 5e16 cm⁻³ to 1e18 cm⁻³. The body well region 108 may be helpful for reducing an ON resistance of the high voltage transistor including the plurality of transistor cells.

In accordance with an exemplary embodiment of the present invention, for each one of the plurality of transistor cells, a RESURF region 110 may optionally be formed below and/or surrounding the body region 105, the body well region 108 (if any is formed) and the drift region 109 of each one of the plurality of transistor cells in the substrate 100S (e.g., in the epitaxial layer 102 for the example of FIG. 1). In an embodiment, the RESURF region 110 of each one of the plurality of transistor cells may be of the first conductivity type (e.g., P type). In the example of FIG. 1, the RESURF region 110 is illustratively shown as a P region. The RESURF region 110 may have a RESURF dopant concentration. In an embodiment, the RESURF dopant concentration of the RESURF region 110 may be lower than the body dopant concentration of the body region 105 and/or lower than the body well dopant concentration of the body well region 108 (if any is formed). In an embodiment, the RESURF dopant concentration of the of the RESURF region 110 may be in a range from 5e15cm⁻³ to 5e17 cm⁻³. The RESURF region 110 may be helpful for reducing an on resistance of the high voltage transistor and/or improving the breakdown voltage of the high voltage transistor.

The semiconductor device 100 in accordance with various embodiments of the present invention may have a vertical junction breakdown control distance d6 which may in the example of FIG. 1 refer to a vertical direct distance measured or inspected substantially from a bottom surface S7 of the RESURF region 110 to the peak dopant concentration plane S6 of the tub bottom layer 14 of the tub. A maximum distance value of the vertical junction breakdown control distance d6 of the semiconductor device 100 that is available or fabricable in accordance with various embodiments of the present invention may advantageously being improved, for instance being greater than that of prior art semiconductor devices can achieve. This is at least in one aspect because the buried depth d5 of the tub bottom layer 14 in the semiconductor device 100 in accordance with various embodiments of the present invention may be greater than it would be possible in the prior art semiconductor devices. The vertical junction breakdown control distance d6 is one of a plurality of key factors influencing a high voltage tolerance performance of the semiconductor device 100. For instance, a larger vertical junction breakdown control distance d6 may be beneficial to increasing a vertical junction breakdown voltage Vjbt between the body region 105 and the tub bottom layer 14, which is beneficial to increasing the breakdown voltage of the high voltage transistor or an overall high voltage tolerance capacity of the semiconductor device 100. That is, the vertical junction breakdown voltage Vjbt between the body region 105 and the tub bottom layer 14 may essentially increase with an increase in the vertical junction breakdown control distance d6 or with an increase in the buried depth d5 of the tub bottom layer 14.

In the existing technologies, one of the major bottle necks for developing a transistor such as a high voltage MOS transistor that is adapted to be used for high voltage applications requiring the transistor to have a high voltage tolerance capacity (e.g., over 70V, especially up to above 100V) may lie in a limited vertical junction breakdown voltage Vjbb between a body and a buried layer which is formed in an initial substrate layer that is below an epitaxial layer of the transistor. The buried layer is generally used for isolating the body from the initial substrate layer of the transistor. In the existing technologies, for example, it is very hard to increase the vertical junction breakdown voltage Vjbb of a conventional transistor to over 70V up to especially over 100V. One way to improve the vertical junction breakdown voltage Vjbb is to thicken the epitaxial layer of the conventional transistor since thicker epitaxial layer would allow the body to be further distanced away from the buried layer. This should be effective for fabricating transistors to meet the voltage tolerance requirements for low voltage to medium voltage (e.g., no greater than 70V) applications. However, when it comes to the attempt to produce high voltage transistors with a high withstand voltage (e.g., over 70V up to especially over 100V), further thickening the epitaxial layer (e.g., using two or more steps of epitaxy process to make the epitaxial layer a multi-layered thick epitaxial layer) encounters other technical difficulties including an issue of uneasy or even unable to link the buried layer formed in an initial substrate layer that is below the multi-layered (e.g., two or more layered) thick epitaxial layer to pickups that are formed near a top surface of the multi-layered thick epitaxial layer. Linking the buried layer to the pickups by for example doped well regions having the same doped conductivity type as that of the buried layer and the pickups to form a tub is important so that the high voltage transistor can be disposed in the tub just as described with the example of the semiconductor device 100.

Unfortunately, even with introducing a high energy implantation process along with long drive-in and hot thermal (or high temperature, e.g., 1100˜1200° C.) steps, it would become very hard to form the doped well regions that could be diffused deep enough to link the pickups with the buried layer in the multi-layered thick epitaxial layer having a thickness that would be enough (for example of about over 10 μm) to support a high enough vertical junction breakdown voltage Vjbb (for example over 70V up to especially over 100V) between the body and the buried layer of the conventional transistor. Besides, in current semiconductor manufacturing process technologies, there is not much room to keep the high temperature long drive-in implantation steps.

Alternatively, deep trenched pickups reaching the buried layer may be used, but it involves complicated and expensive process steps. In addition, the process steps of forming the deep trenched pickups itself could create reliability, defect issues. Furthermore, even using the deep trench techniques, the maximum distance from the body to the buried layer that can be achievable or fabricable has its limits due to limits in a maximum achievable buried depth (e.g., di as shown in FIG. 3) of the buried layer formed with the conventional low energy (e.g., keV level) implantation process as mentioned above, making it still a bottle neck to form transistors with a high withstand voltage for example over 70V up to especially over 100V.

The semiconductor device 100 in accordance with various embodiments of the present invention makes it possible to break the bottle neck which has been a long unresolved need to address. Advantages of various embodiments of the present invention may include but not limited to enable manufacturing of a semiconductor device including a high voltage transistor with a high withstand voltage for example over 70V up to over 100V, which is conventionally very hard to archive even with using very thick multi-layered (e.g., two or more layered) epitaxial layer requiring two or more steps of epitaxy process and/or long drive-in and very hot thermal (or high temperature e.g., 1100˜1200° C.) implantation process and/or deep trenched pickups technology. For example, the semiconductor device 100 according to an embodiment can have a high voltage transistor with a breakdown voltage substantially of about 100V to 250V formed with the epitaxial layer 102 of a thickness essentially ranging from 8 μm to 16 μm, which is almost impossible to achieve in the existing technologies. Manufacturing process of the semiconductor device 100 in accordance with various embodiments of the present invention may just require one additional masking step compatible with the typical manufacturing process, which is simple and cost effective.

In accordance with an exemplary embodiment of the present invention, the semiconductor device 100 further comprises a substrate routing structure that may include a substrate pickup region 111 and a substrate linking well region 112. The substrate routing structure may serve to provide a route of the first conductivity to electrically lead the substrate 100S out. The substrate pickup region 111 may be formed in the substrate 100S and disposed adjacent the top surface S1 of the substrate 100S. The substrate pickup region 111 can be isolated from the tub pickup region 11 for instance by a shallow trench isolation structure (“STI”) 114. The substrate pickup region 111 may be of the first conductivity type (e.g., P type) and may have a substrate pickup dopant concentration so that the substrate pickup region 111 may serve/function as a contact region of the substrate 100S that allows the substrate 100S being electrically coupled to for example a metal contact (herein after referred to as a substrate metal contact) which may be formed atop the substrate pickup region 111. The substrate pickup region 111 may help to form an Ohmic contact between the substrate 100S and the substrate metal contact, and thus may be referred to as being “highly doped” or “heavily doped” by those skilled in the art (e.g., illustrated as a P+ region in FIG. 1). The substrate linking well region 112 may be formed surrounding the substrate pickup region 111 in the substrate 100S (e.g., in the epitaxial layer 102 for the example of FIG. 1). In an embodiment, the substrate linking well region 112 may be of the first conductivity type (e.g., P type). In the example of FIG. 1, the substrate linking well region 112 is illustratively shown as a P region. The substrate linking well region 112 may have a substrate linking well dopant concentration that is lower than the substrate pickup dopant concentration of the substrate pickup region 111. The substrate linking well region 112 may be helpful for reducing a routing resistance from the substrate 100S to the metal contact for electrically leading the substrate 100S out.

In accordance with an exemplary embodiment of the present invention, the substrate routing structure of the semiconductor device 100 may optionally further include a substrate deep linking well region 113. The substrate deep linking well region 113 may optionally be formed below and/or surrounding the substrate linking well region 112 in the substrate 100S (e.g., in the epitaxial layer 102 for the example of FIG. 1). In an embodiment, the substrate deep linking well region 113 may be of the first conductivity type (e.g., P type). In the example of FIG. 1, the substrate deep linking well region 113 is illustratively shown as a P region. The substrate deep linking well region 113 may have a substrate deep linking well dopant concentration that is lower than the substrate linking well dopant concentration of the substrate linking well region 112. The substrate deep linking well region 113 may be helpful for further reducing the routing resistance from the substrate 100S to the metal contact for electrically leading the substrate 100S out.

While a limited portion encompassing the high voltage transistor of the semiconductor device 100 is exemplarily shown in the drawings, it will be understood that the semiconductor device 100 may further include other elements that are not shown.

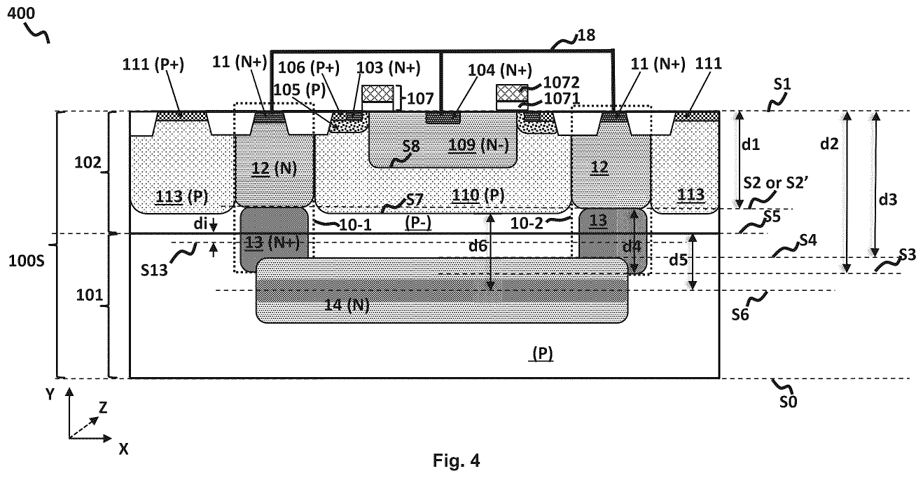

FIG. 4 illustrates a partial cross-sectional view of a semiconductor device 400, including for instance a transistor in accordance with an alternative embodiment of the present invention. Compared with the semiconductor device 100 shown in FIG. 1, the semiconductor device 400 shown in FIG. 4 may optionally have the body well region 108 of each one of the plurality of transistor cells omitted. One of ordinary skill in the art would understand that most of the above descriptions to the semiconductor device 100 made with reference to FIG. 1 are applicable to the semiconductor device 400 in the example of FIG. 4 except that the body well region 108 may not be formed in the example of FIG. 4.

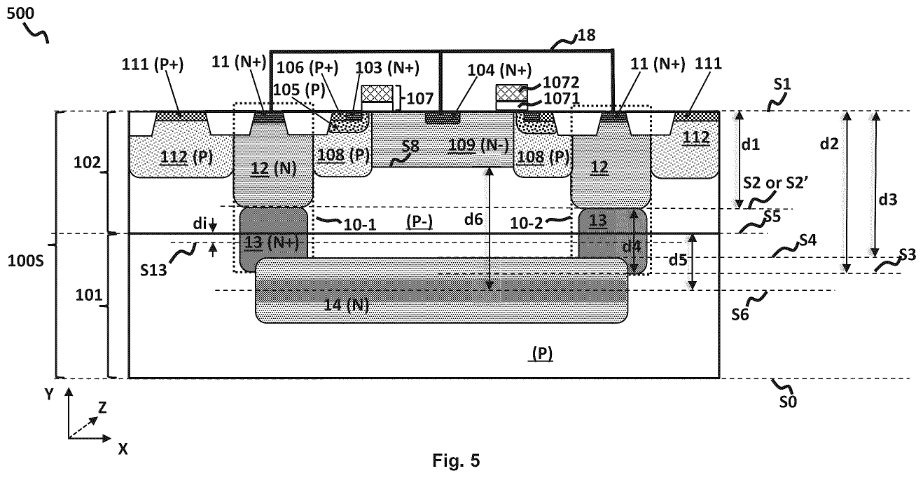

FIG. 5 illustrates a partial cross-sectional view of a semiconductor device500, including for instance a transistor in accordance with an alternative embodiment of the present invention. Compared with the semiconductor device 100 shown in FIG. 1, the semiconductor device 500 shown in FIG. 5 may optionally have the RESURF region 110 of each one of the plurality of transistor cells omitted. One of ordinary skill in the art would understand that most of the above descriptions to the semiconductor device 100 made with reference to FIG. 1 are applicable to the semiconductor device 500 in the example of FIG. 5 except that the RESURF region 110 may not be formed in the example of FIG. 5. For this situation, the vertical junction breakdown control distance d6 may in the example of FIG. 5 refer to a vertical direct distance inspected substantially from a bottom surface S8 of the drift region 109 to the peak dopant concentration plane S6 of the tub bottom layer 14 of the tub.

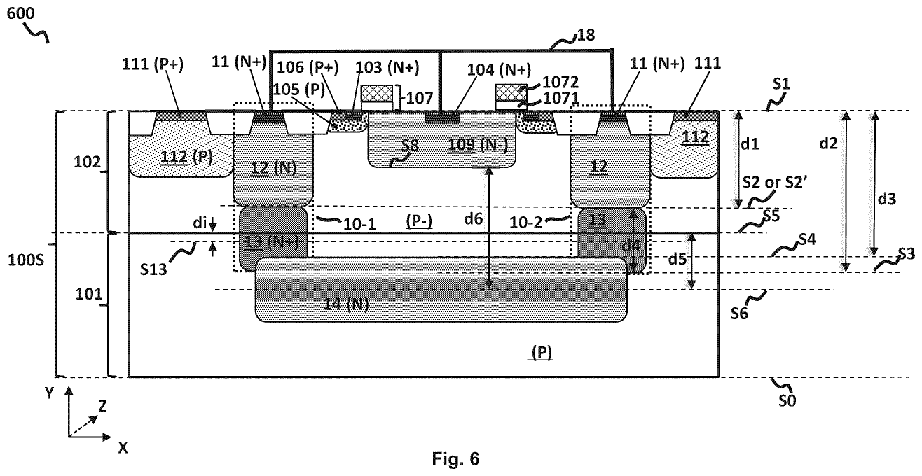

FIG. 6 illustrates a partial cross-sectional view of a semiconductor device 600, including for instance a transistor in accordance with an alternative embodiment of the present invention. Compared with the semiconductor device 100 shown in FIG. 1, the semiconductor device 600 shown in FIG. 6 may optionally have both the body well region 108 and the RESURF region 110 of each one of the plurality of transistor cells omitted.

One of ordinary skill in the art would understand that most of the above descriptions to the semiconductor device 100 made with reference to FIG. 1 are applicable to the semiconductor device 600 in the example of FIG. 6 except that the body well region 108 and the RESURF region 110 may not be formed in the example of FIG. 6. For this situation, the vertical junction breakdown control distance d6 may in the example of FIG. 5 refer to a vertical direct distance inspected substantially from a bottom surface S8 of the drift region 109 to the peak dopant concentration plane S6 of the tub bottom layer 14 of the tub.

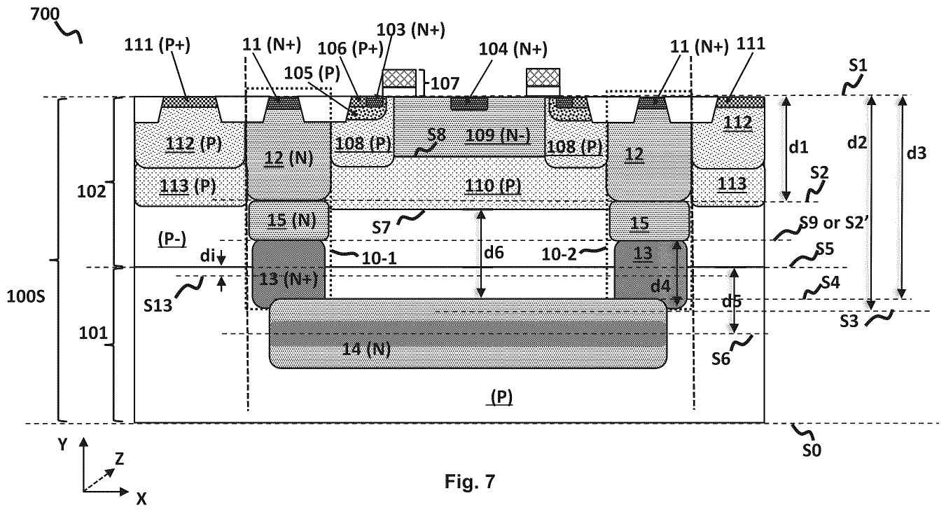

FIG. 7 illustrates a partial cross-sectional view of a semiconductor device 700, including for instance a transistor in accordance with an alternative embodiment of the present invention. One of ordinary skill in the art would understand that most of the above descriptions to the semiconductor device 100 made with reference to FIG. 1 are applicable to the semiconductor device 700 in the example of FIG. 7. Difference in one aspect may lie in that, in the semiconductor device 700, each one of the plurality of tub sidewalls 10 of the tub may further include a tub wall linking region 15, for instance, referring to the illustration for the tub left sidewall 10-1 or the tub right sidewall 10-2 in the example of FIG. 1 for ease of understanding.

The tub wall linking region 15 of each tub sidewall 10 may be formed and disposed between the tub well region 12 and the tub buried link region 13. The tub wall linking region 15 may be of the second conductivity type (e.g., N type in the example of FIG. 7). The tub wall linking region 15 may physically contact the tub well region 12 above and the tub buried link region 13 below to provide an electrical connection between the tub well region 12 and the tub buried link region 13 which physically contacts the tub bottom layer 14 so that an electrical path of the second conductivity type (e.g., N type) from the tub pickup region 11 to the tub bottom layer 14 may be formed.

In the example shown in FIG. 7, the tub wall linking region 15 may extend from the bottom surface S2 of the tub well region 12 vertically down in the substrate 100S, for instance, into the epitaxial layer 102 with a bottom surface S9 of the tub wall linking region 15 substantially reach and contact with the tub buried link region 13. The tub buried link region 13 may extend from the bottom surface S9 of the tub wall linking region 15 vertically down in the substrate 100S, for instance, into the initial substrate layer 101 with the bottom surface S3 of the tub buried link region 13 substantially reaching a tub link depth d2 away from the top surface S1 of the substrate 100S to contact with the tub bottom layer 14. One of ordinary skill in the art would understand that in the example of FIG. 7, the bottom surface S2 of the tub well region 12 may be substantially coincide and coplanar with a top surface of the tub wall linking region 15, while the bottom surface S9 of the tub wall linking region 15 may be substantially coincide and coplanar with the top surface S2′ of the tub buried link region 13. One of ordinary skill in the art would further understand that in an actual semiconductor device, an interface between adjacent doped regions (such as the interface S2 between the tub well region 12 and the tub wall linking region 15, the interface S9/S2′ between the tub wall linking region 15 and the tub buried link region 13) may not be as neat, distinct, and clear as theoretically shown in the illustrative drawings of various embodiments of the present disclosure. It is possible that adjacent doped regions may penetrate each other at the interface due to the diffusion of doped ions during the manufacturing process, making the interface blurred but roughly identifiable. The tub wall linking region 15 may advantageously help to make it possible to further enhance the breakdown voltage of the high voltage transistor formed in the tub 10 of the semiconductor device 700.

It should also be understood that variations like those described with reference to FIG. 4 to FIG. 6 may be made based on the semiconductor device 700. For instance, in an embodiment, for a semiconductor device that is a variant from the semiconductor device 700, the body well region 108 of each one of the plurality of transistor cells may optionally not be formed compared with the semiconductor device 700 shown in FIG. 7. In an embodiment, for a semiconductor device that is another variant from the semiconductor device 700, the RESURF region 110 of each one of the plurality of transistor cells may optionally not be formed compared with the semiconductor device 700 shown in FIG. 7. In an embodiment, for a semiconductor device that is still another variant from the semiconductor device 700, both the body well region 108 and the RESURF region 110 of each one of the plurality of transistor cells may optionally not be formed compared with the semiconductor device 700 shown in FIG. 7.

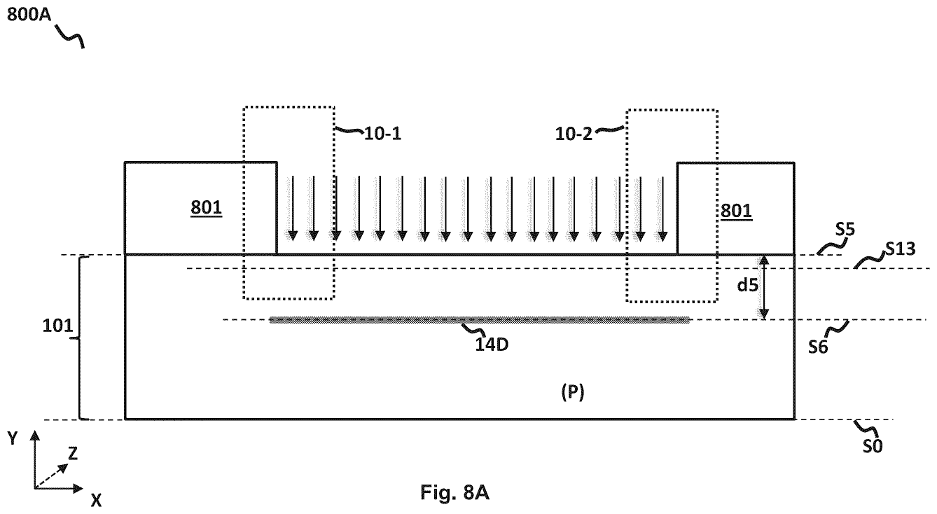

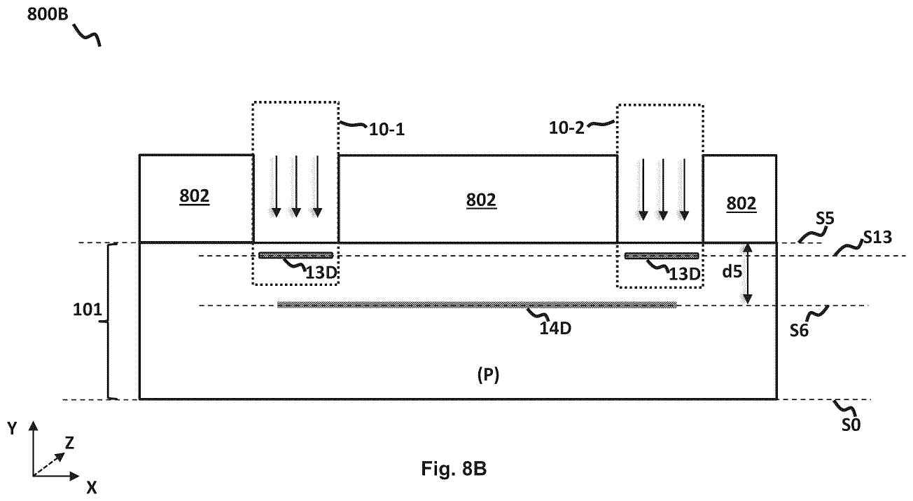

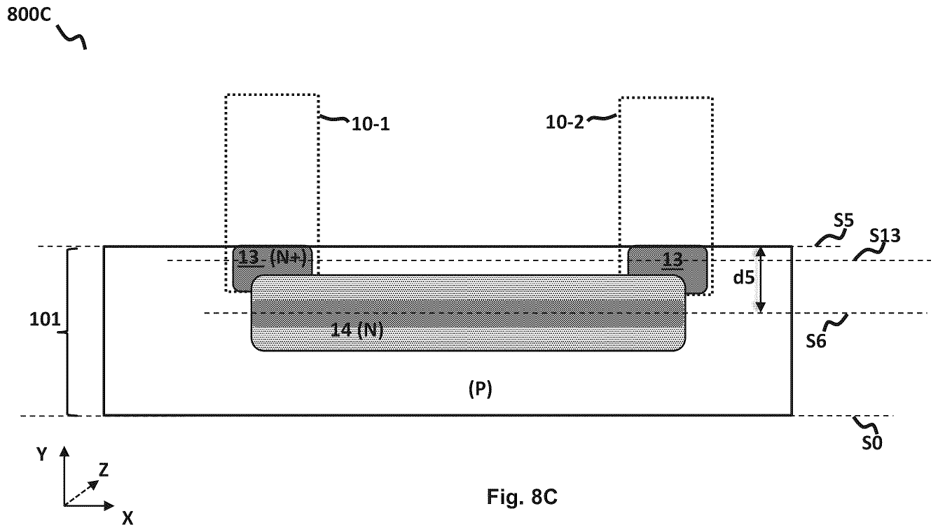

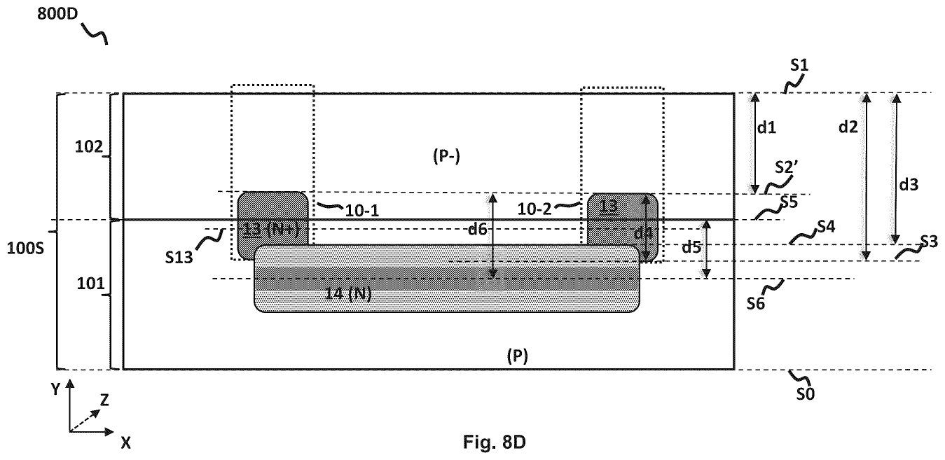

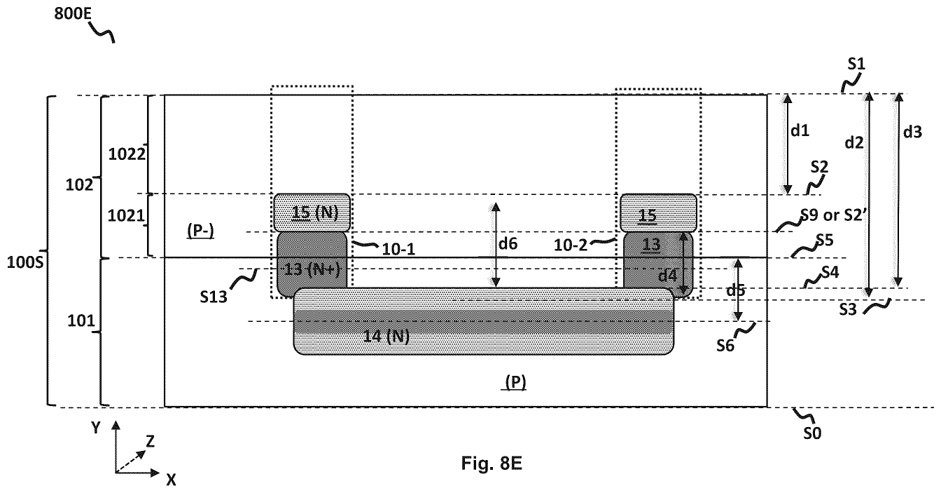

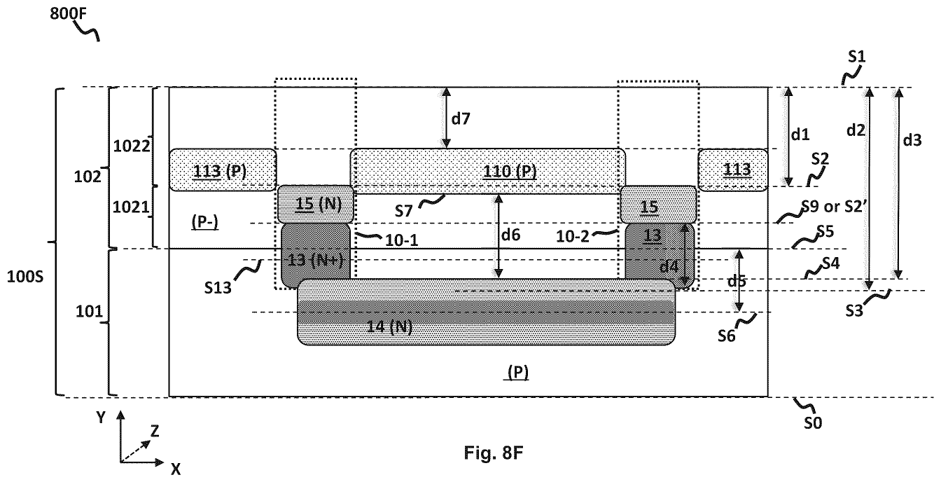

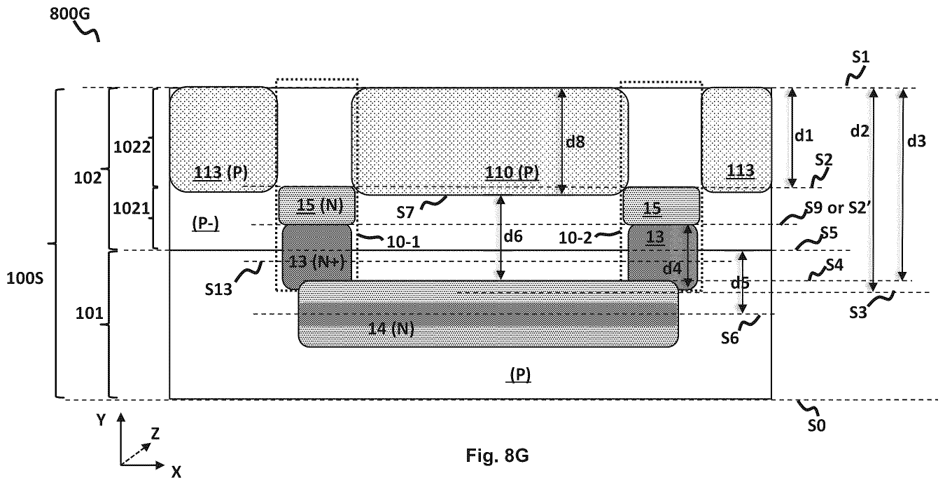

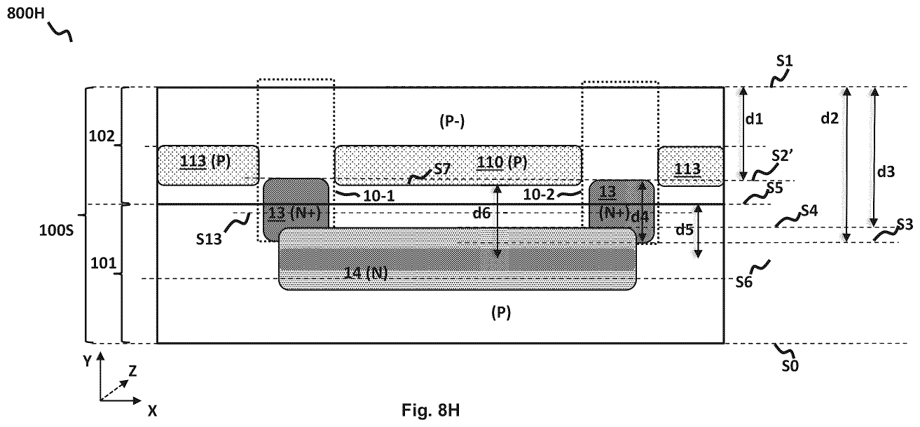

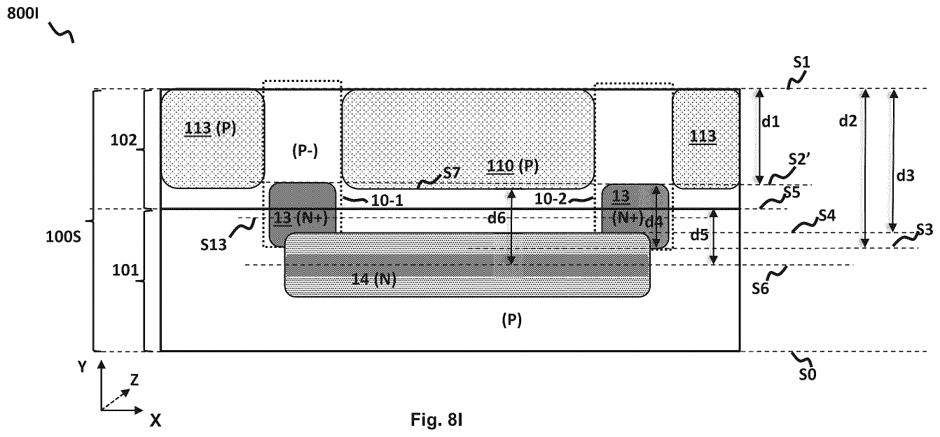

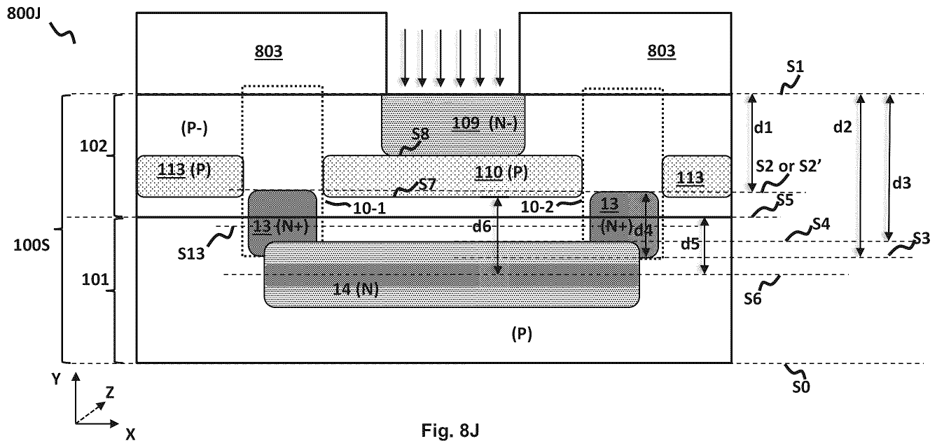

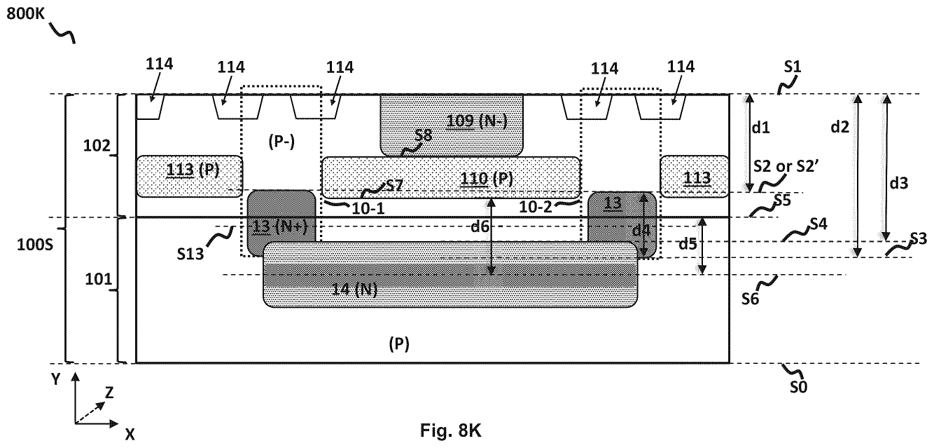

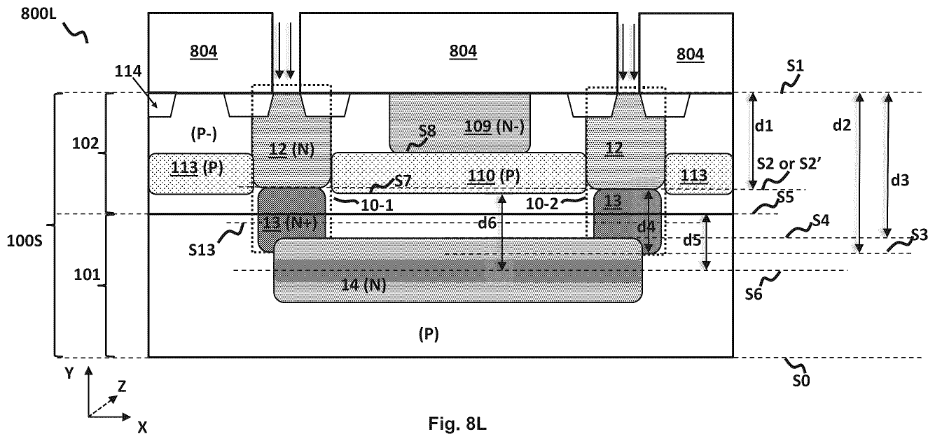

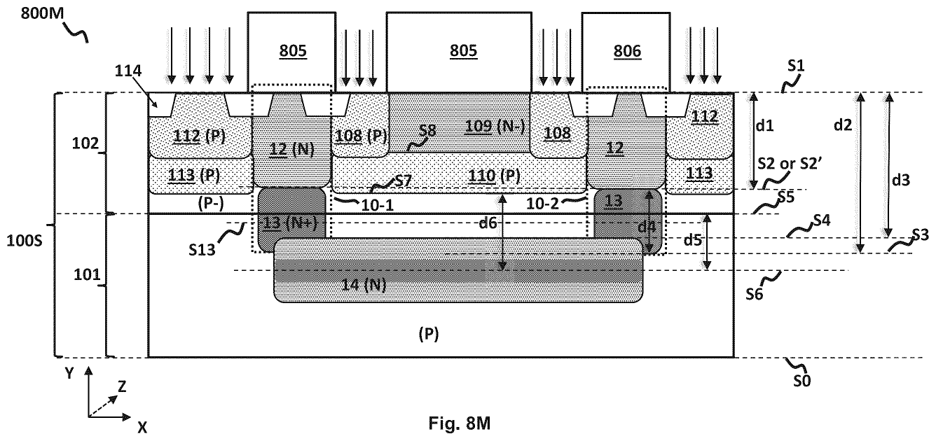

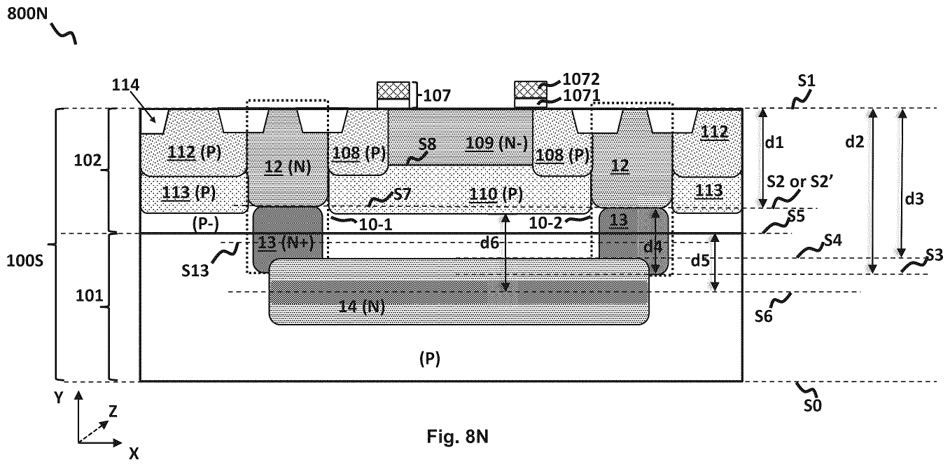

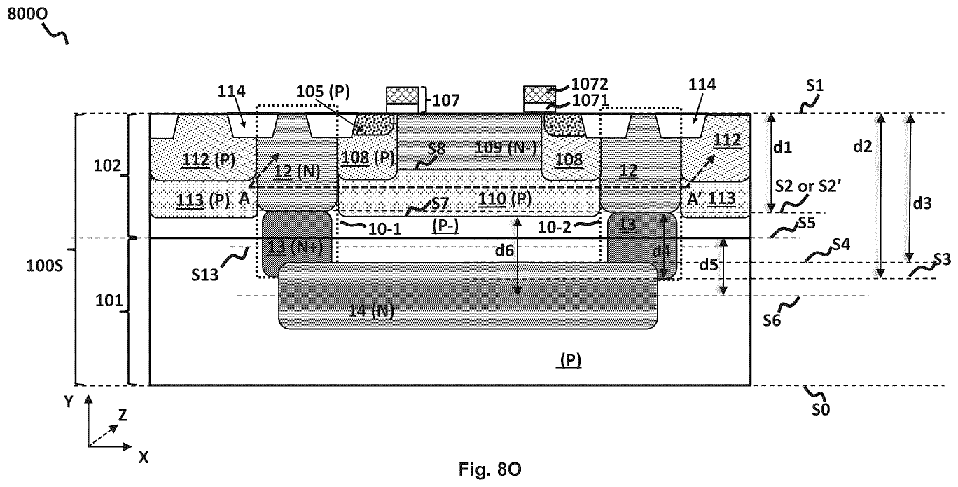

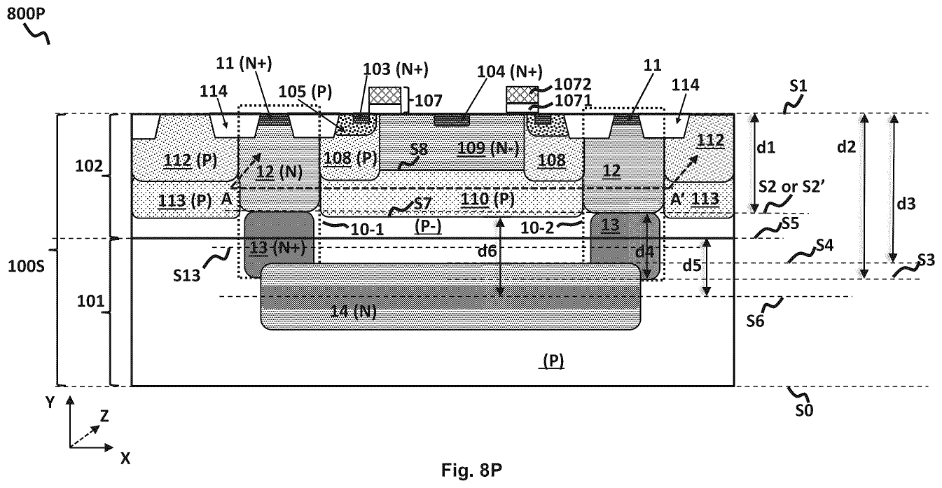

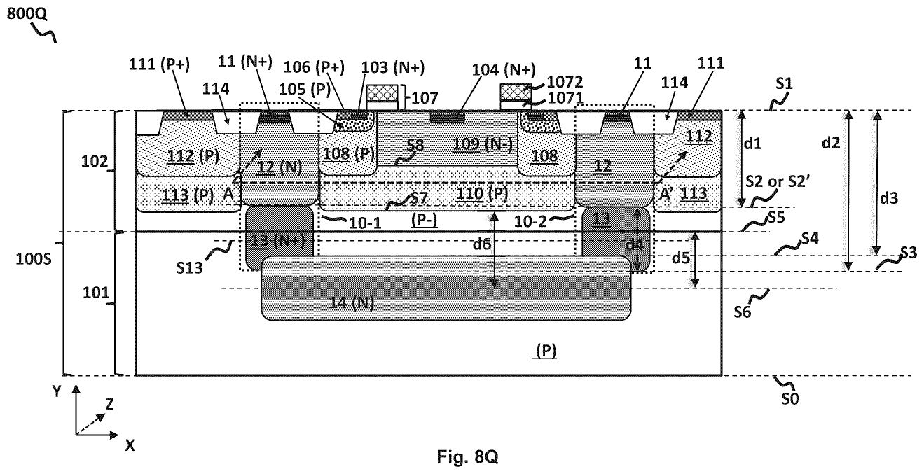

FIG. 8A to FIG. 8Q illustrate partial cross-sectional views of some process stages of a method for manufacturing a semiconductor device in accordance with an embodiment of the present invention. For example, at least one of the semiconductor devices mentioned in the above-described embodiments with reference to FIG. 1 to FIG. 7 can be formed. The cross-sectional views in FIG. 8A to FIG. 8Q may be considered as illustrated out in a 3-dimensional coordinate system having the x axis, y axis and z axis perpendicular to one another. It may be understood that the illustrative cross-sectional views are inspected from/taken from a cutting plane parallel to the x-y plane defined by the x and y axis. It may be understood that each one of the cross-sectional views may be an illustrative cross-sectional image showing a portion where a high voltage transistor of the semiconductor device (e.g., the semiconductor device 100, or 400, or 500, or 600, or 700 or their variants) is designated to be formed at a certain process stage described in conjunction with that cross-sectional view. One of ordinary skill in the art would understand that the high voltage transistor may comprise a plurality of (i.e. one or more) transistor cells and may be disposed in a tub in a substrate (e.g., the substrate 100S) of the semiconductor device to be manufactured as disclosed in various embodiments described with reference to FIG. 1 to FIG. 7 above.

Referring to FIG. 8A to FIG. 8D, a substrate (e.g., the substrate 100S) of the first conductivity type (e.g., P type) can be prepared. In an example, the substrate 100S includes a semiconductor layer (e.g., the initial substrate layer 101 as shown in FIG. 1) of the first conductivity type (e.g., P type) and an epitaxial layer 102 which may be formed on the initial substrate layer 101. It should be understood that in accordance with some embodiments, during preparing the substrate 100S, buried doped regions and/or buried layers may be formed in the substrate 100S, for example in the initial substrate layer 101 or in the epitaxial layer 102 with doping processes for instance.

In the step as illustratively shown with an example structure 800A in FIG. 8A, the semiconductor layer (e.g., the initial substrate layer 101) may firstly be provided. In subsequence, dopants of the second conductivity type (e.g., N type), such as Phosphorus (P), that are suitable for and compatible with the high energy implantation process may be implanted in the initial substrate layer 101 from the top surface S5 of the initial substrate layer 101 under the shield of a patterned implantation mask 801. The patterned implantation mask 801 can be formed on the top surface S5 of the initial substrate layer 101 and be patterned to expose pre-defined areas on top surface S5 of the initial substrate layer 101 where dopants to form the tub bottom layer 14 of the tub of the semiconductor device 100 would be implanted in. Dopants for forming the tub bottom layer 14 may be implanted in the initial substrate layer 101 to form a buried implanted zone 14D located at substantially the implanting-in plane S6 for the tub bottom layer 14. The patterned implantation mask 801 may be removed after the implantation processes for forming the tub bottom layer 14 are completed. More details such as location, conductivity type (or dopant type) and dopant concentration of the tub bottom layer 14 to be formed can be understood in conjunction with reference to the descriptions already made with reference to FIG. 1 and will not need to be repeated here for simplicity.

In the step as illustratively shown with an example structure 800B in FIG. 8B, dopants of the second conductivity type (e.g., N type), such as Antimony (Sb) or Arsenic (As), that are suitable for and compatible with the low energy implantation process may be implanted in the initial substrate layer 101 from the top surface S5 of the initial substrate layer 101 under the shield of a patterned implantation mask 802. The patterned implantation mask 802 may be formed on the top surface S5 of the initial substrate layer 101 and be patterned to expose pre-defined areas on the top surface S5 of the initial substrate layer 101 where dopants to form the tub buried link region 13 of each one of the plurality of tub sidewalls 10 of the tub of the semiconductor device 100 would be implanted in. For instance, a tub left sidewall 10-1 and a tub right sidewall 10-2 among the plurality of tub sidewalls 10 is exemplarily illustrated out in the cross-sectional views. Dopants for forming the tub buried link region 13 may be implanted in the initial substrate layer 101 to form a buried implanted zone 13D located at substantially the implanting-in plane S13 for the tub buried link region 13 of each one of the plurality of tub sidewalls 10. The patterned first implantation mask 801 may be removed after the implantation processes for forming the tub buried link region 13 are completed. More details such as location, conductivity type (or dopant type) and dopant concentration of the tub buried link region 13 to be formed can be understood in conjunction with reference to the descriptions already made with reference to FIG. 1 and will not be repeated here for simplicity. One of ordinary skill in the art would understand that the steps shown in FIG. 8A and FIG. 8B may not be necessarily performed in an order as described here. In alternative embodiments, it is possible to perform the step shown in FIG. 8B ahead of the step shown in FIG. 8A.

Now referring to FIG. 8C, a drive in process is performed so that the dopants of the second conductivity type (e.g., N type) that are implanted in the initial substrate layer 101 in the steps as shown in FIG. 8A and FIG. 8B are diffused. The buried implanted zone 13D is diffused to form the tub buried link region 13 of each one of the plurality of tub sidewalls 10, and the buried implanted zone 14D is diffused to form the tub bottom layer 14, as can be understood with an example structure 800C illustratively shown in FIG. 8C.

In the step as illustratively shown with an example structure 800D in FIG. 8D, the epitaxial layer 102 may be formed on the initial substrate layer 101. The epitaxial layer 102 may be a single layered epitaxial layer formed with a single epitaxial step or a multi-layered epitaxial layer formed with two or more epitaxial steps depending on practical device specifications such as break down voltage, on resistance and so on of the high voltage transistor to be formed in the substrate 100S. More details such as composition, conductivity type (or dopant type) and dopant concentration of the epitaxial layer 102 can be understood in conjunction with reference to the descriptions already made with reference to FIG. 1 and will not be repeated here for simplicity. One of ordinary skill in the art would understand that the tub buried link region 13 of each one of the plurality of tub sidewalls 10 may partially extend up into the epitaxial layer 102 after formation of the epitaxial layer 102 due to the phenomenon of auto-doping as previously described with reference to FIG. 1 and as illustratively shown in FIG. 8D. It should also be understood that throughout the process of forming the epitaxial layer 102, it is possible to have some buried doped regions and/or buried layers formed in the epitaxial layer 102 with doping processes for instance.

In an embodiment, referring to an example structure 800E illustratively shown in FIG. 8E for example, a tub wall linking region 15 of the second conductivity type (e.g., N type) for each one of the plurality of tub sidewalls 10 of the tub may optionally be formed with any suitable doping processes in the epitaxial layer 102 of the substrate 100S. It can be understood that the process for forming the tub wall linking region 15 may be performed for embodiments of manufacturing a semiconductor device that includes a tub having the tub wall linking region 15 in each one of the plurality of tub sidewalls 10 of the tub, like the semiconductor device 700 shown and described with reference to FIG. 7. For instance, dopants of the second conductivity type (e.g., N type) may be implanted in the epitaxial layer 102 at a plurality of predetermined locations under the shield of a patterned implantation mask to form the tub wall linking region 15 for each one of the plurality of tub sidewalls 10. The patterned implantation mask to form the tub wall linking regions 15 may be removed after the implantation processes for forming the tub wall linking region 15 for each one of the plurality of tub sidewalls 10 are completed. The tub wall linking region 15 for each one of the plurality of tub sidewalls 10 may be a buried doped region that is buried substantially at a predetermined tub wall linking depth (e.g., which may be substantially identical to the tub well depth d1 of the tub well region 12 to be formed) in the epitaxial layer 102, for example buried in a lower portion 1021 of the epitaxial layer 102. For this situation, the epitaxial layer 102 may be a multi-layered epitaxial layer formed with two or more epitaxial steps as mentioned with reference to FIG. 8D. Doping processes (such as implanting dopants of the second conductivity type in the lower portion 1021 of the epitaxial layer 102) for forming the tub wall linking region 15 for each one of the plurality of tub sidewalls 10 can be performed between the epitaxial steps for forming the lower portion 1021 and an upper portion 1022 atop the lower portion 2021 of the epitaxial layer 102, which could be easily understood by those skilled in the art and need not to be addressed in detail herein. More details such as location, conductivity type (or dopant type) and dopant concentration of the tub wall linking region 15 for each one of the plurality of tub sidewalls 10 have been described with reference to FIG. 7 and will not need to be repeated here for simplicity. It can also be understood that the process for forming the tub wall linking region 15 needs not to be performed for embodiments of manufacturing a semiconductor device that includes a tub without the tub wall linking region 15 included in each one of the plurality of tub sidewalls 10 of the tub, like the semiconductor device 100 shown and described with reference to FIG. 1.

In an embodiment, referring to an example structure 800F illustratively shown in FIG. 8F for example, a RESURF region 110 of the first conductivity type (e.g., P type) for each one of the plurality of transistor cells of the high voltage transistor to be manufactured in the substrate 100S (e.g., in the epitaxial layer 102) may optionally be formed with any suitable doping processes. A substrate linking deep well region 113 of the first conductivity type (e.g., P type) may be formed sharing the same doping process as for forming the RESURF region 110 of each one of the plurality of transistor cells of the high voltage transistor. For instance, dopants of the first conductivity type (e.g., P type) may be implanted in the epitaxial layer 102 at a plurality of predetermined locations under the shield of a patterned implantation mask to form the RESURF regions 110 and the substrate deep linking well regions 113. In an embodiment, the patterned implantation mask for forming the RESURF regions 110 and the substrate deep linking well regions 113 can be removed after the implantation processes for forming the RESURF region 110 for each one of the plurality of transistor cells and the substrate deep linking well regions 113 are completed. In an embodiment, the RESURF region 110 of each one of the plurality of transistor cells may be a buried doped region that is buried substantially at a predetermined RESURF buried depth d7 in the epitaxial layer 102, for example as illustrated in FIG. 8F. The predetermined RESURF buried depth d7 could be smaller or shallower than the predetermined tub wall linking depth (e.g., substantially identical to the tub well depth d1) when inspected or measured with reference to or relative to the top surface S1 of the epitaxial layer 102. For the example illustrated in FIG. 8F, the substrate linking deep well region 113 which can be formed in the same doping process as for forming the RESURF regions 110 also presents as a buried doped region.

In an alternative embodiment, referring to an example structure 800G illustratively shown in FIG. 8G, the RESURF region 110 of each one of the plurality of transistor cells may not necessarily be formed as a buried doped region, but can alternatively be formed as a doped region that extends from the top surface S1 into the epitaxial layer substantially with a predetermined RESURF depth d8. The substrate linking deep well region 113 which can be formed in the same doping process as for forming the RESURF regions 110 would present as a doped region that extends from the top surface S1 into the epitaxial layer substantially with the predetermined RESURF depth d8 too for the example shown in FIG. 8G. Dopants of the first conductivity type (e.g., P type) for forming the RESURF regions 110 and the substrate deep linking well regions 113 may be implanted from the top surface S1 of the epitaxial layer 102 into the epitaxial layer 102, which could be easily understood by those skilled in the art and need not to be addressed in detail herein. More details such as location, conductivity type (or dopant type) and dopant concentration of the RESURF region 110 of each one of the plurality of transistor cells of the high voltage transistor to be manufactured in the substrate 100S and that of the substrate deep linking well regions 113 can be understood in conjunction with reference to the descriptions already made with reference to FIG. 1 and will not need to be repeated here for simplicity.

In the examples illustratively shown in FIGS. 8F and 8G, the process for forming the RESURF region 110 for each one of the plurality of transistor cells of the high voltage transistor and for forming the substrate linking deep well region 113 can be considered as being performed based on the structure 800E of FIG. 8E for embodiments of manufacturing a semiconductor device that includes the tub having the tub wall linking region 15 in each one of the plurality of tub sidewalls 10 of the tub and the high voltage transistor having the RESURF region 110, like the semiconductor device 700.

In an alternative embodiment, referring to an example structure 800H illustratively shown in FIG. 8H or an example structure 800I illustratively shown in FIG. 8I, the process for forming the RESURF region 110 for each one of the plurality of transistor cells of the high voltage transistor and for forming the substrate linking deep well region 113 can be considered as being performed based on the structure 800D of FIG. 8D for embodiments of manufacturing a semiconductor device that includes the tub not having the tub wall linking region 15 in each one of the plurality of tub sidewalls 10 of the tub and the high voltage transistor having the RESURF region 110, like the semiconductor device 100 or 400.

Therefore, it can be understood that the process for forming the RESURF region 110 for each one of the plurality of transistor cells of the high voltage transistor may be performed for embodiments of manufacturing a semiconductor device that includes the high voltage transistor having the RESURF region 110, like the semiconductor device 100, or 400, or 700. It can also be understood that the process for forming the RESURF region 110 for each one of the plurality of transistor cells of the high voltage transistor needs not to be performed for embodiments of manufacturing a semiconductor device that includes the high voltage transistor without the RESURF region 110 included in each one of the plurality of transistor cells, like the semiconductor device 500, or 600.

In the step as illustratively shown with an example structure 800J in FIG. 8J, a drift region 109 of the second conductivity type (e.g., N type) for each one of the plurality of transistor cells of the high voltage transistor to be manufactured in the substrate 100S (e.g., in the epitaxial layer 102 for the example of FIG. 1) may be formed with any suitable doping processes. For instance, dopants of the second conductivity type (e.g., N type) may be implanted in the epitaxial layer 102 at a plurality of predetermined locations under the shield of a patterned implantation mask 803 to form the drift regions 109 of the plurality of transistor cells of the high voltage transistor to be manufactured. In an embodiment, the patterned implantation mask 803 is formed on the top surface S1 of the epitaxial layer 102 and is patterned to expose pre-defined areas on top surface S1 of the epitaxial layer 102 where dopants to form the drift region 109 of each one of the plurality of transistor cells of the high voltage transistor would be implanted in. The patterned implantation mask 803 may be removed after the implantation processes for forming the drift region 109 for each one of the plurality of transistor cells are completed. In the example illustrated in FIG. 8J, the doping process for forming the drift regions 109 of the plurality of transistor cells of the high voltage transistor is shown to be performed based on the structure 800H exemplarily and illustratively shown in FIG. 8H. However, it should be understood that the doping process for forming the drift regions 109 described here can obviously be performed based on any one of the structures 800D to 800I respectively shown in FIG. 8D to FIG. 8I depending on whether the semiconductor device to be manufactured includes the tub having the tub wall linking region 15 in each one of the plurality of tub sidewalls 10 of the tub and/or the RESURF region 110 for each one of the plurality of transistor cells of the high voltage transistor. More details such as location, conductivity type (or dopant type) and dopant concentration of the drift region 109 of each one of the plurality of transistor cells of the high voltage transistor to be manufactured in the substrate 100S can be understood in conjunction with reference to the descriptions already made with reference to FIG. 1 and will not need to be repeated here for simplicity.

In the step as illustratively shown with an example structure 800K in FIG. 8K, a plurality of shallow trench isolation (“STI”) structures 114 are formed. In an embodiment, the plurality of STI structures 114 are formed by opening a corresponding plurality of shallow trenches from the top surface S1 of the epitaxial layer 102 in the epitaxial layer 102 under the shield of a patterned trench etching mask with an etching process for example and then filling the plurality of shallow trenches with an insulation material.

In the step as illustratively shown with an example structure 800L in FIG. 8L, a tub well region 12 of the second conductivity type (e.g., N type) for each one of the plurality of tub sidewalls 10 (e.g., 10-1 and 10-2 illustratively shown in the cross sectional view) of the tub to be manufactured in the substrate 100S may be formed with any suitable doping processes. For instance, dopants of the second conductivity type (e.g., N type) may be implanted in the epitaxial layer 102 at a plurality of predetermined locations under the shield of a patterned implantation mask 804 to form the tub well region 12 of each one of the plurality of tub sidewalls 10 of the tub to be formed. In an embodiment, the patterned implantation mask 804 is formed on the top surface S1 of the epitaxial layer 102 and is patterned to expose pre-defined areas on the top surface S1 of the epitaxial layer 102 where dopants to form the tub well region 12 of each one of the plurality of tub sidewalls 10 would be implanted in. According to an example, with the shield of the patterned implantation mask 804, dopants of the second conductivity type (e.g., Phosphorus) suitable for and compatible with the medium to high energy implantation process (e.g., a few hundred keV level to several MeV level implantation process) can be implanted from the top surface S1 into the epitaxial layer 102 using the medium to high energy implantation process to form the tub well region 12 of each one of the plurality of tub sidewalls 10. The patterned implantation mask 804 may be removed after the implantation processes for forming the tub well region 12 of each one of the plurality of tub sidewalls 10 are completed. More details such as location, conductivity type (or dopant type) and dopant concentration of the tub well region 12 of each one of the plurality of tub sidewalls 10 of the tub to be manufactured in the substrate 100S can be understood in conjunction with reference to the descriptions already made with reference to FIG. 1 and will not need to be repeated here for simplicity.

In the step as illustratively shown with an example structure 800M in FIG. 8M, a body well region 108 of the first conductivity type (e.g., P type) for each one of the plurality of transistor cells of the high voltage transistor to be manufactured in the substrate 100S (e.g., in the epitaxial layer 102) may optionally be formed with any suitable doping processes. A substrate linking well region 112 of the first conductivity type (e.g., P type) may be formed sharing the same doping process as for forming the body well region 108 of each one of the plurality of transistor cells of the high voltage transistor. For instance, dopants of the first conductivity type (e.g., P type) may be implanted in the epitaxial layer 102 at a plurality of predetermined locations under the shield of a patterned implantation mask 805 to form the body well regions 108 and the substrate linking well regions 112. In an embodiment, the patterned implantation mask 805 is formed on the top surface S1 of the epitaxial layer 102 and is patterned to expose pre-defined areas on the top surface S1 of the epitaxial layer 102 where dopants to form the body well region 108 of each one of the plurality of transistor cells and the substrate linking well regions 112 would be implanted in. According to an example, with the shield of the patterned implantation mask 805, dopants of the first conductivity type (e.g., P type) can be implanted from the top surface S1 into the epitaxial layer 102 to form the body well regions 108 of the plurality of transistor cells of the high voltage transistor and the substrate linking well regions 112. The patterned implantation mask 805 may be removed after the implantation processes for forming the body well regions 108 and the substrate linking well regions 112 are completed. More details such as location, conductivity type (or dopant type) and dopant concentration of the tub well region 12 of each one of the body well region 108 of each one of the plurality of transistor cells of the high voltage transistor to be manufactured in the substrate 100S can be understood in conjunction with reference to the descriptions already made with reference to FIG. 1 and will not need to be repeated here for simplicity. It can be understood that the process for forming the body well region 108 of each one of the plurality of transistor cells may be performed for embodiments of manufacturing a semiconductor device that includes the high voltage transistor having the body well region 108, like the semiconductor device 100, or 500 or 700. It can also be understood that the process for forming the body well region 108 of each one of the plurality of transistor cells of the high voltage transistor needs not to be performed for embodiments of manufacturing a semiconductor device that includes the high voltage transistor without the body well region 108 included in each one of the plurality of transistor cells, like the semiconductor device 400, or 600.

In the step as illustratively shown with an example structure 800N in FIG. 8N, a gate region 107 for each one of the plurality of transistor cells of the high voltage transistor to be manufactured may be formed. The gate region 107 may take various structures that do not depart from the spirit and scope of the present invention as already described with reference to the example of FIG. 1.

In the step as illustratively shown with an example structure 800O in FIG. 8O, a body region 105 of the first conductivity type (e.g., P type) for each one of the plurality of transistor cells of the high voltage transistor to be manufactured in the substrate 100S may be formed with any suitable doping processes. For instance, dopants of the first conductivity type (e.g., P type) may be implanted in the epitaxial layer 102 at a plurality of predetermined locations under the shield of a patterned implantation mask to form the body region 105 of each one of the plurality of transistor cells. In an embodiment, the patterned implantation mask for forming the body regions 105 can be removed after the implantation processes for forming the body region 105 for each one of the plurality of transistor cells are completed. More details such as location, conductivity type (or dopant type) and dopant concentration of the body region 105 of each one of the plurality of transistor cells of the high voltage transistor to be manufactured in the substrate 100S can be understood in conjunction with reference to the descriptions already made with reference to FIG. 1 and will not need to be repeated here for simplicity.

In the step as illustratively shown with an example structure 800P in FIG. 8P, a source region 103 and a drain region 104 of the second conductivity type (e.g., N type) for each one of the plurality of transistor cells of the high voltage transistor to be manufactured in the substrate 100S may be formed with any suitable doping processes. A tub pickup region 11 for each one of the plurality of tub sidewalls 10 (e.g., 10-1 and 10-2) of the tub can be formed sharing the same doping process as for forming the source regions 103 and the drain regions 104 of the plurality of transistor cells. For instance, dopants of the second conductivity type (e.g., N type) may be implanted in the epitaxial layer 102 at a plurality of predetermined locations under the shield of a patterned implantation mask to form the source regions 103, the drain regions 104, and the tub pickup regions 11. In an embodiment, the patterned implantation mask for forming the source regions 103, the drain regions 104, and the tub pickup regions 11 can be removed after the implantation processes for forming these regions are completed. More details such as location, conductivity type (or dopant type) and dopant concentration of the source regions 103, the drain regions 104, and the tub pickup regions 11 can be understood in conjunction with reference to the descriptions already made with reference to FIG. 1 and will not need to be repeated here for simplicity.

In the step as illustratively shown with an example structure 800Q in FIG. 8Q, a body contact region 106 of the first conductivity type (e.g., P type) for each one of the plurality of transistor cells of the high voltage transistor to be manufactured in the substrate 100S may be formed with any suitable doping processes. A substrate pickup region 111 for the substrate routing structure which serves to electrically lead the substrate 100S out can be formed sharing the same doping process as for forming the body contact regions 106 of the plurality of transistor cells. For instance, dopants of the first conductivity type (e.g., P type) may be implanted in the epitaxial layer 102 at a plurality of predetermined locations under the shield of a patterned implantation mask to form the body contact regions 106 and the substrate pickup regions 111. In an embodiment, the patterned implantation mask for forming the body contact regions 106 and the substrate pickup regions 111 can be removed after the implantation processes for forming these regions are completed. More details such as location, conductivity type (or dopant type) and dopant concentration of the body contact regions 106 and the substrate pickup regions 111 can be understood in conjunction with reference to the descriptions already made with reference to FIG. 1 and will not need to be repeated here for simplicity.

In the examples illustrated in FIG. 8J to FIG. 8Q, related manufacturing steps described with reference to these figures are shown to be performed based on the structure 800H exemplarily and illustratively shown in FIG. 8H.

However, it should be understood that the manufacturing steps described here with reference to FIG. 8J to FIG. 8Q can obviously be performed based on any one of the structures 800D to 800I respectively shown in FIG. 8D to FIG. 8I depending on whether the semiconductor device to be manufactured includes the tub having the tub wall linking region 15 in each one of the plurality of tub sidewalls 10 of the tub and/or whether the semiconductor device to be manufactured includes the RESURF region 110 for each one of the plurality of transistor cells of the high voltage transistor.

For instance, a method for manufacturing a semiconductor device, like the semiconductor device 500 or 600 that includes a tub with each one of the plurality of tub sidewalls 10 not having the tub wall linking region 15 and a high voltage transistor not having the RESURF region 110, may include the manufacturing steps as illustrated and described with reference to FIG. 8A to FIG. 8D, and FIG. 8J to FIG. 8Q, where the manufacturing steps described with reference to FIG. 8J to FIG. 8Q can be performed based on the structures 800D shown in FIG. 8D.

For another instance, a method for manufacturing a semiconductor device, like the semiconductor device 100 or 400 that includes a tub with each one of the plurality of tub sidewalls 10 not having the tub wall linking region 15 and a high voltage transistor having the RESURF region 110, may include the manufacturing steps as illustrated and described with reference to FIG. 8A to FIG. 8D, FIG. 8H or FIG. 8I, and FIG. 8J to FIG. 8Q, where manufacturing steps described with reference to FIG. 8J to FIG. 8Q can be performed based on the structure 800H shown in FIG. 8H or the structure 800I shown in FIG. 8I.

For still another instance, a method for manufacturing a semiconductor device, like the semiconductor device 700 that includes a tub with each one of the plurality of tub sidewalls 10 including the tub wall linking region 15 and a high voltage transistor including the RESURF region 110, may include the manufacturing steps as illustrated and described with reference to FIG. 8A to FIG. 8D, FIG. 8E, FIG. 8F or FIG. 8G, and FIG. 8J to FIG. 8Q, where manufacturing steps described with reference to FIG. 8J to FIG. 8Q can be performed based on the structure 800F shown in FIG. 8F or the structure 800G shown in FIG. 8G.

For yet another instance, a method for manufacturing a semiconductor device that includes a tub with each one of the plurality of tub sidewalls 10 including the tub wall linking region 15 and a high voltage transistor not including the RESURF region 110, which can be understood in conjunction with FIG. 5 and FIG. 7, or in conjunction with FIG. 6 and FIG. 7, may include the manufacturing steps as illustrated and described with reference to FIG. 8A to FIG. 8D, FIG. 8E, and FIG. 8J to FIG. 8Q, where manufacturing steps described with reference to FIG. 8J to FIG. 8Q can be performed based on the structure 800E shown in FIG. 8E.

Those skilled in the art should understand that the above descriptions to the semiconductor devices (such as the semiconductor devices100, 400 ˜700) and related manufacturing methods of the various embodiments of the present disclosure made with reference to FIG. 1 to FIG. 8Q are just to provide examples and do not intend to be limiting. The advantages of the various embodiments of the present invention are not confined to those described above. These and other advantages of the various embodiments of the present invention will become more apparent upon reading the whole detailed descriptions and studying the various figures of the drawings.

From the foregoing, it will be appreciated that specific embodiments of the present invention have been described herein for purposes of illustration, but that various modifications may be made without deviating from the technology. Many of the elements of one embodiment may be combined with other embodiments in addition to or in lieu of the elements of the other embodiments.

What is claimed is:

1. A method for forming a semiconductor device, comprising:
forming a substrate of a first conductivity type that includes a tub bottom layer of a tub; wherein
the tub bottom layer is of a second conductivity type that is opposite to the first conductivity type; and wherein
the tub bottom layer has a tub bottom layer peak dopant concentration plane that is substantially away from a top surface of an initial substrate layer of the substrate for a predetermined tub bottom layer buried depth that is essentially greater than 0.5 μm.

2. The method of claim 1, wherein the predetermined tub bottom layer buried depth is essentially in a range from 1 μm to 5 μm.

3. The method of claim 1, wherein the substrate is formed to further include a tub buried link region for each one of a plurality of tub sidewalls of the tub, and wherein the tub buried link region at least contacts with the tub bottom layer.

4. The method of claim 3, wherein the tub bottom layer is buried deeper than the tub buried link region in the substrate.

5. The method of claim 3, wherein the tub buried link region is formed in the initial substrate layer and has a tub buried link peak dopant concentration plane that is substantially away from the top surface of the initial substrate layer for a predetermined tub buried link buried depth that is smaller than the predetermined tub bottom layer buried depth.

6. The method of claim 5, wherein the predetermined tub bottom layer buried depth is essentially of 0.5 μm to 3.5 μm deeper than the predetermined tub buried link buried depth when inspected or measured with reference to the top surface of the initial substrate layer.

7. The method of claim 1, wherein forming the substrate includes:
providing the initial substrate layer of the first conductivity type;
implanting dopants of the second conductivity type that are suitable for and compatible with a high energy implantation process in the initial substrate layer from the top surface of the initial substrate layer to form a first buried implanted zone located at substantially an implanting-in plane with the predetermined tub bottom layer buried depth; and
performing a drive in process so that the first buried implanted zone is diffused to form the tub bottom layer.

8. The method of claim 7, wherein forming the substrate further includes:
implanting dopants of the second conductivity type that are suitable for and compatible with a low energy implantation process in the initial substrate layer from the top surface of the initial substrate layer to form a second buried implanted zone for each one of a plurality of tub sidewalls of the tub, wherein the second buried implanted zone is located at substantially an implanting-in plane with a predetermined tub buried link buried depth; and
sharing the drive in process so that the second buried implanted zone is diffused to form a tub buried link region for each one of the plurality of tub sidewalls.

9. The method of claim 1, wherein forming the substrate further includes:
forming an epitaxial layer on the initial substrate layer, wherein the epitaxial layer has a thickness in a range from 8 μm to 16 μm.

10. The method of claim 9, further comprising:
forming a drift region of the second conductivity type for each one of a plurality of transistor cells of a high voltage transistor to be manufactured in the substrate.

11. The method of claim 10, further comprising:
forming a RESURF region of the first conductivity type for each one of the plurality of transistor cells of the high voltage transistor in the epitaxial layer.

12. The method of claim 11, wherein the RESURF region of each one of the plurality of transistor cells is a buried doped region that is buried substantially at a predetermined RESURF buried depth in the epitaxial layer.

13. The method of claim 11, wherein the RESURF region of each one of the plurality of transistor cells is a doped region that extends from a top surface of the substrate into the epitaxial layer substantially with a predetermined RESURF depth.

14. The method of claim 9, further comprising:
forming a tub wall linking region of the second conductivity type for each one of a plurality of tub sidewalls of the tub in the epitaxial layer, wherein the tub wall linking region is a buried doped region that is buried substantially at a predetermined tub wall linking depth in the epitaxial layer.

15. The method of claim 14, wherein forming the epitaxial layer includes:
forming a lower portion of the epitaxial layer on the initial substrate layer;
forming the tub wall linking region for each one of the plurality of tub sidewalls by a doping process in the lower portion of the epitaxial layer; and
forming an upper potion of the epitaxial layer on the lower portion of the epitaxial layer.

16. The method of claim 9, further comprising:
forming a plurality of shallow trench isolation structures at a plurality of predetermined locations in the epitaxial layer.

17. The method of claim 3, further comprising:
forming a tub well region of the second conductivity type for each one of the plurality of tub sidewalls, wherein the tub well region extends vertically from a top surface of the substrate into the substrate until contacting with or connecting to the tub buried link region.

18. The method of claim 14, further comprising:
forming a tub well region of the second conductivity type for each one of the plurality of tub sidewalls, wherein the tub well region extends vertically from a top surface of the substrate into the substrate until contacting with or connecting to the tub wall linking region.

19. The method of claim 10, further comprising:
forming a body well region of the first conductivity type for each one of the plurality of transistor cells of the high voltage transistor to be manufactured in the substrate, wherein the body well region is aside the drift region.

20. The method of claim 10, further comprising:
forming a gate region for each one of the plurality of transistor cells of the high voltage transistor;
forming a body region of the first conductivity type for each one of the plurality of transistor cells of the high voltage transistor in the substrate, wherein the body region is separated from the drift region;
forming a source region and a drain region of the second conductivity type for each one of the plurality of transistor cells of the high voltage transistor;
forming a tub pickup region for each one of a plurality of tub sidewalls of the tub sharing the same process for forming the source region and the drain region; and
forming a body contact region of the first conductivity type for each one of the plurality of transistor cells of the high voltage transistor.

21. The method of claim 1, wherein the predetermined tub bottom layer buried depth is essentially in a range from 1 μm to 3.5 μm.

22. The method of claim 1, wherein the tub bottom layer is doped with Phosphorus or other dopants that are suitable for and compatible with a high energy implantation process.

23. The method of claim 1, wherein the tub bottom layer has a tub bottom layer dopant concentration that is substantially of 1e1 cm⁻³ to 1e3 cm⁻³ lower than a dopant concentration of a buried region or buried layer that would be formed in the initial substrate layer with a low energy implantation process.

24. The method of claim 3, wherein the tub buried link region is doped with Antimony or Arsenic or other dopants of the second conductivity type that are suitable for and compatible with a low energy implantation process in the initial substrate layer.

25. The method of claim 9, wherein the thickness of the epitaxial layer is formed to be of 10 μm to 16 μm to support forming of a high voltage transistor having a breakdown voltage substantially of 100V to 250V.

26. A method for forming a semiconductor device, comprising:
providing an initial substrate layer of a substrate of a first conductivity type;
forming a tub bottom layer of a tub of a second conductivity type in the initial substrate layer, the second conductivity type being opposite to the first conductivity type; and
forming a tub buried link region for each one of a plurality of tub sidewalls of the tub, wherein the tub buried link region is formed to at least contact with the tub bottom layer, and wherein the tub bottom layer is buried deeper in the substrate than the tub buried link region with reference to a top surface of the initial substrate layer.

27. The method of claim 26, wherein a bottom surface of the tub bottom layer is deeper than a bottom surface of the tub buried link region when inspected with reference to the top surface of the initial substrate layer.

28. The method of claim 26, wherein an implanting-in plane of the tub bottom layer is substantially away from a top surface of the initial substrate layer with a predetermined buried depth that is essentially greater than 0.5 μm.

29. The method of claim 26, wherein an implanting-in plane of the tub bottom layer is deeper than an implanting-in plane of the tub buried link region when inspected or measured with reference to the top surface of the initial substrate layer.

30. The method of claim 26, wherein the implanting-in plane of the tub bottom layer is essentially of 0.5 μm to 3.5 μm deeper than the implanting-in plane of the tub buried link region when inspected or measured with reference to the top surface of the initial substrate layer.

31. The method of claim 26, wherein the implanting-in plane of the tub bottom layer is essentially of 1 μm to 2 μm deeper than the implanting-in plane of the tub buried link region when inspected or measured with reference to the top surface of the initial substrate layer.

32. The method of claim 26, wherein forming the tub bottom layer includes implanting in Phosphorus or other dopants of the second conductivity type that are suitable for and compatible with a high energy implantation process in the initial substrate layer.

33. The method of claim 26, wherein forming the tub buried link region for each one of a plurality of tub sidewalls includes implanting in Antimony or Arsenic or other dopants of the second conductivity type that are suitable for and compatible with a low energy implantation process in the initial substrate layer.

34. The method of claim 26, wherein the tub bottom layer is doped with a tub bottom layer dopant concentration that is substantially of 1e1 cm⁻³ to 1e3 cm⁻³ lower than a tub link dopant concentration of the tub buried link region.

35. The method of claim 26, wherein the tub bottom layer is doped with a tub bottom layer dopant concentration essentially in a range from 5e15 cm⁻³ to 1e19 cm⁻³.

36. The method of claim 26, wherein the tub buried link region is doped with a tub link dopant concentration essentially in a range from 1e17 cm⁻³ to 1e20 cm⁻³.

37. The method of claim 26, further comprising:
forming an epitaxial layer on the initial substrate layer, wherein the epitaxial layer is formed to have a thickness substantially ranging from 8 μm to 16 μm.

38. The method of claim 37, further comprising:
forming the plurality of tub sidewalls of the tub; and
forming a high voltage transistor inside the tub.

39. The method of claim 37, wherein forming the high voltage transistor includes:
forming a drift region of the second conductivity type for each one of a plurality of transistor cells of the high voltage transistor in the epitaxial layer;
forming a plurality of shallow trench isolation structures at a plurality of predetermined locations in the epitaxial layer;
forming a gate region for each one of the plurality of transistor cells;
forming a body region of the first conductivity type for each one of the plurality of transistor cells, wherein the body region is separated from the drift region;
forming a source region of the second conductivity type in the body region and a drain region of the second conductivity type in the drift region for each one of the plurality of transistor cells; and
forming a body contact region of the first conductivity type in the body region for each one of the plurality of transistor cells.

40. The method of claim 39, wherein forming the high voltage transistor further includes:
forming a RESURF region of the first conductivity type for each one of the plurality of transistor cells before forming the drift region, wherein the RESURF region is a buried doped region that is buried below the drift region or a doped region that extends from a top surface of the epitaxial layer down into the epitaxial layer to substantially below and surround the drift region.

41. The method of claim 39, wherein forming the high voltage transistor further includes:
forming a body well region of the first conductivity type for each one of the plurality of transistor cells before forming the body region, wherein the body well region is next to the drift region, and wherein the body region is formed in the body well region.

42. The method of claim 38, wherein forming the plurality of tub sidewalls includes:
forming a tub well region of the second conductivity type for each one of the plurality of tub sidewalls, wherein the tub well region extends vertically from a top surface of the epitaxial layer down into the epitaxial layer until contacting with or connecting to the tub buried link region; and
forming a tub pickup region in the tub well region for each one of the plurality of tub sidewalls.

43. The method of claim 38, wherein forming the plurality of tub sidewalls includes:
forming a tub wall linking region of the second conductivity type in the epitaxial layer atop the tub buried link region for each one of the plurality of tub sidewalls, wherein the tub buried link region contacts with or connects to the tub buried link region below;
forming a tub well region of the second conductivity type for each one of the plurality of tub sidewalls in the epitaxial layer, wherein the tub well region extends vertically from a top surface of the epitaxial layer down into the epitaxial layer to contact with or connect to the wall linking region; and
forming a tub pickup region in the tub well region for each one of the plurality of tub sidewalls.
